(19) United States
(12) Patent Application Publication
(10) Pub. No.: US 2026/0113063 A1
(43) Pub. Date: Apr. 23, 2026

(54) RADIO FREQUENCY CIRCUIT AND COMMUNICATION DEVICE

(71) Applicant: Murata Manufacturing Co., Ltd., Nagaokakyo-shi (JP)

(72) Inventors: Morio TAKEUCHI, Nagaokakyo-shi (JP); Hirotsugu MORI, Nagaokakyo-shi (JP)

(73) Assignee: Murata Manufacturing Co., Ltd., Nagaokakyo-shi (JP)

(21) Appl. No.: 19/424,205

(22) Filed: Dec. 18, 2025

Related U.S. Application Data
(63) Continuation of application No. PCT/JP2024/013549, filed on Apr. 2, 2024.

(30) Foreign Application Priority Data
Jun. 23, 2023 (JP) 2023-103356

(51) Int. Cl. H04B 1/00; H03F 3/24; H04B 1/40; H04L 5/14

(52) U.S. Cl. CPC H04B 1/0078; H03F 3/245; H04B 1/40; H04L 5/14; H03F 2200/294; H03F 2200/451

(57) ABSTRACT

A radio frequency circuit includes first and second filters for first and second time division duplex (TDD) bands. Third and fourth filters cover third and fourth bands. A switch including a first terminal, a second terminal, and a third terminal to connect these filter to an antenna. The first terminal is connected to only the first filter and the second terminal is connected to only the second filter, among the filters having acoustic wave filters. The third terminal connects to both the third filter and the fourth filter. This configuration enables simultaneous transfer of a transmission signal of the first band and a reception signal of the second band, as well as simultaneous transfer of signals of the third and fourth bands. By isolating the TDD filters on separate terminals, signal quality and isolation are improved during simultaneous operation.

### CROSS-REFERENCE TO RELATED APPLICATIONS

This is a continuation application of PCT International Application No. PCT/JP2024/013549 filed on Apr. 2, 2024, designating the United States of America, which is based on and claims priority of Japanese Patent Application No. 2023-103356 filed on Jun. 23, 2023. The entire disclosures of the above-identified applications, including the specifications, drawings, and claims are incorporated herein by reference in their entirety.

### BACKGROUND

### 1. Field

The present disclosure relates to a radio frequency (RF) circuit and a communication device.

### 2. Description of the Related Art

In 3rd Generation Partnership Project (3GPP, registered trademark), simultaneous Rx/Tx of simultaneously performing transmission and reception by combining two time division duplex (TDD) bands has been studied.

### SUMMARY

The present disclosure provides an RF circuit and a communication device with improved signal quality in simultaneous Rx/Tx.

To achieve the above and other advantages, a radio frequency circuit according to an aspect of the present disclosure includes a first filter that has a pass band including a first band for time division duplex and that includes an acoustic wave resonator; a second filter that has a pass band including a second band for time division duplex and that includes an acoustic wave resonator; a third filter that has a pass band including a transmission band or a reception band of a third band; a fourth filter that has a pass band including a transmission band or a reception band of a fourth band; and a first switch including a first terminal, a second terminal, a third terminal, and a first antenna connection terminal. The first band and the second band constitute a band combination capable of simultaneously transferring one of a transmission signal and a reception signal of the first band and the other of a transmission signal and a reception signal of the second band. The third band and the fourth band constitute a band combination capable of simultaneously transferring a signal of the third band and a signal of the fourth band. The first band, the second band, the third band, and the fourth band constitute a band combination capable of simultaneously transferring at least one of a signal of the first band and a signal of the second band and at least one of a signal of the third band and a signal of the fourth band. The first terminal is connected to only the first filter among the filters including an acoustic wave resonator. The second terminal is connected to only the second filter among the filters including an acoustic wave resonator. The third terminal is connected to the third filter and the fourth filter.

A radio frequency circuit according to an aspect of the present disclosure includes a first filter that has a pass band including a first band for time division duplex and that includes an acoustic wave resonator; a second filter that has a pass band including a second band for time division duplex and that includes an acoustic wave resonator; a third filter that has a pass band including a transmission band or a reception band of a third band; a fourth filter that has a pass band including a transmission band or a reception band of a fourth band; and a first switch including a first terminal, a second terminal, and a first antenna connection terminal. The first band and the second band constitute a band combination capable of simultaneously transferring one of a transmission signal and a reception signal of the first band and the other of a transmission signal and a reception signal of the second band. The third band and the fourth band constitute a band combination capable of simultaneously transferring a signal of the third band and a signal of the fourth band. The first band, the second band, the third band, and the fourth band constitute a band combination capable of simultaneously transferring at least one of a signal of the first band and a signal of the second band and at least one of a signal of the third band and a signal of the fourth band. The first terminal is connected to only the first filter and the second filter among the filters including an acoustic wave resonator. The second terminal is connected to the third filter and the fourth filter.

According to the present disclosure, an RF circuit and a communication device with improved signal quality in simultaneous Rx/Tx is provided.

### BRIEF DESCRIPTION OF THE DRAWINGS

FIG. 1 is a circuit configuration diagram of a radio frequency (RF) circuit and a communication device according to a first embodiment;

FIG. 2A is a diagram illustrating a first connection manner in the RF circuit according to the first embodiment;

FIG. 2B is a diagram illustrating a second connection manner in the RF circuit according to the first embodiment;

FIG. 3A is a diagram illustrating a first connection manner in an RF circuit according to a first modification of the first embodiment;

FIG. 3B is a diagram illustrating a second connection manner in the RF circuit according to the first modification of the first embodiment;

FIG. 4A is a diagram illustrating a first connection manner in an RF circuit according to a second modification of the first embodiment;

FIG. 4B is a diagram illustrating a second connection manner in the RF circuit according to the second modification of the first embodiment;

FIG. 5 is a diagram illustrating a first connection manner in an RF circuit according to a third modification of the first embodiment;

FIG. 6 is a diagram illustrating a third connection manner in an RF circuit according to a fourth modification of the first embodiment;

FIG. 7A is a diagram illustrating a first connection manner in an RF circuit according to a second embodiment;

FIG. 7B is a diagram illustrating a first connection manner in an RF circuit according to a fifth modification of the second embodiment; and

FIG. 7C is a diagram illustrating a first connection manner in an RF circuit according to a sixth modification of the second embodiment.

### DESCRIPTION OF THE EMBODIMENTS

Hereinafter, embodiments of the present disclosure will be described in detail with reference to the drawings. The embodiments described below each illustrate a general or specific example. The numerical values, shapes, materials, constituent elements, the disposition and connection manner of the constituent elements, and so forth described in the following embodiments are merely examples, and are not intended to limit the present disclosure.

The drawings are schematic diagrams drawn with emphasis, omission, or ratio adjustment performed as appropriate in order to illustrate the present disclosure. The illustration therein is not necessarily strict, and may be different from actual shapes, positional relationships, and ratios. In the drawings, constituent elements that are substantially the same are denoted by the same reference numerals, and a repeated description thereof may be omitted or simplified.

In the present disclosure, “connected” includes not only a direct connection using a connection terminal and/or a wiring conductor, but also an electrical connection via another circuit element. “Connected between A and B” means connected to A and B on a path connecting A and B.

In the present disclosure, a “transmission path” means a transfer line constituted by a wiring line through which a radio frequency (RF) transmission signal propagates, an electrode directly connected to the wiring line, a terminal directly connected to the wiring line or the electrode, and so forth. A “reception path” means a transfer line constituted by a wiring line through which an RF reception signal propagates, an electrode directly connected to the wiring line, a terminal directly connected to the wiring line or the electrode, and so forth.

In a circuit configuration, a “terminal” means a point at which a conductor in an element terminates. In a case where the impedance of a conductor between elements is sufficiently low, a terminal can be interpreted as not only a single point but also any point on the conductor between the elements or the entire conductor.

In the present disclosure, the pass band of a filter is defined as a frequency band between two frequencies greater by 3 dB than a minimum value of insertion loss in the pass band.

### First Embodiment

A communication device 4 according to the present embodiment functions as user equipment (UE) in a cellular network, and is typically a mobile phone, a smartphone, a tablet computer, a wearable device, or the like. The communication device 4 may be an Internet of Things (IoT) sensor device, a medical/health-care device, a vehicle, an unmanned aerial vehicle (UAV) (a so-called drone), or an automated guided vehicle (AGV). The communication device 4 may function as a base station (BS) in a cellular network.

The inventors have recognized that, in an existing RF circuit disclosed in United States Patent Application Publication No. 2015/0133067, degradation of signal quality in simultaneous Rx/Tx is a concern. Accordingly, the present disclosure provides an RF circuit and a communication device with improved signal quality in simultaneous Rx/Tx.

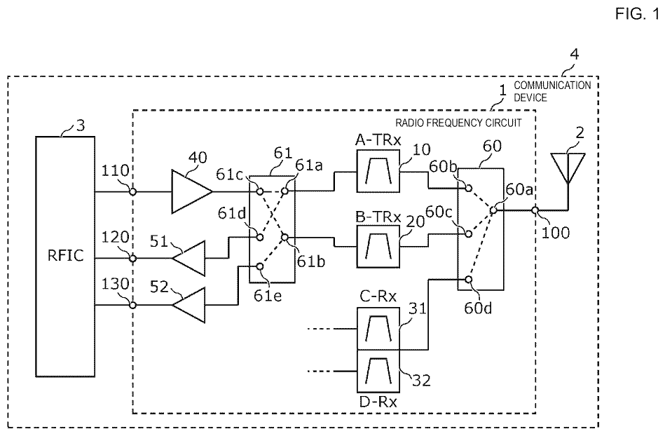

The circuit configurations of the communication device 4 and an RF circuit 1 according to the present embodiment will be described with reference to FIG. 1. FIG. 1 is a circuit configuration diagram of the RF circuit 1 and the communication device 4 according to the first embodiment. In the drawings referenced hereinafter, a broken line in a switch represents a path between terminals connectable to each other.

FIG. 1 illustrates an exemplary circuit configuration. The RF circuit 1 and the communication device 4 can be implemented by using any of a wide variety of circuit implementations and circuit techniques. Thus, the description of the RF circuit 1 and the communication device 4 provided below is not to be construed in a limiting manner.

### 1.1 Circuit Configuration of Communication Device 4

First, the circuit configuration of the communication device 4 according to the present embodiment will be described with reference to FIG. 1. The communication device 4 is implemented in UE and includes the RF circuit 1, an antenna 2, and a radio frequency integrated circuit (RFIC) 3.

The RF circuit 1 transfers an RF signal between the antenna 2 and the RFIC 3. A detailed circuit configuration of the RF circuit 1 will be described below.

The antenna 2 is connected to an antenna terminal 100 of the RF circuit 1, transmits an RF signal output from the RF circuit 1, and receives an RF signal from the outside and outputs the received RF signal to the RF circuit 1.

The RFIC 3 is an example of a signal processing circuit configured to process an RF signal. To be specific, the RFIC 3 performs signal processing such as down-conversion on an RF reception signal (hereinafter referred to as a reception signal) input through a reception path of the RF circuit 1, and outputs the reception signal generated through the signal processing to a baseband signal processing circuit (BBIC). The RFIC 3 performs signal processing such as up-conversion on a transmission signal input from the BBIC, and outputs the RF transmission signal (hereinafter referred to as a transmission signal) generated through the signal processing to a transmission path of the RF circuit 1. The RFIC 3 includes a controller that controls a switch, an amplifier, and so forth included in the RF circuit 1. Some or all of the functions of the controller of the RFIC 3 may be implemented in the outside of the RFIC 3, for example, in the BBIC or the RF circuit 1.

In the communication device 4 according to the present embodiment, the antenna 2 is not an essential constituent element. The communication device 4 may further include one or more antennas in addition to the antenna 2.

### 1.2 Circuit Configuration of RF Circuit 1

Next, the circuit configuration of the RF circuit 1 will be described. As illustrated in FIG. 1, the RF circuit 1 includes filters 10, 20, 31, and 32, switches 60 and 61, a power amplifier 40, low-noise amplifiers 51 and 52, the antenna terminal 100, an RF input terminal 110, and RF output terminals 120 and 130.

The antenna terminal 100 is connected to the antenna 2 and a terminal 60a of the switch 60. The RF input terminal 110 is connected to the RFIC 3 and the power amplifier 40 and serves as a terminal for receiving a transmission signal from the RFIC 3. The RF output terminal 120 is connected to the RFIC 3 and the low-noise amplifier 51 and serves as a terminal for outputting a reception signal to the RFIC 3. The RF output terminal 130 is connected to the RFIC 3 and the low-noise amplifier 52 and serves as a terminal for outputting a reception signal to the RFIC 3.

The filter 10 is an example of a first filter, has a pass band including Band A (first band) for time division duplex (TDD), and includes an acoustic wave resonator. One end of the filter 10 is connected to a terminal 60b (first terminal) of the switch 60 (first switch), and the other end of the filter 10 is connected to a terminal 61a (fourth terminal) of the switch 61 (second switch). The filter 10 is used for transmission and reception in Band A (A-TRx).

The filter 20 is an example of a second filter, has a pass band including Band B (second band) for TDD, and includes an acoustic wave resonator. One end of the filter 20 is connected to a terminal 60c (second terminal) of the switch 60 (first switch), and the other end of the filter 20 is connected to a terminal 61b (fifth terminal) of the switch 61 (second switch). The filter 20 is used for transmission and reception in Band B (B-TRx).

The filters 10 and 20 are each constituted by a surface acoustic wave (SAW) filter, a bulk acoustic wave (BAW) filter, or a combination thereof.

The filter 31 is an example of a third filter, and has a pass band including a reception band (downlink operation band) of Band C (third band) for frequency division duplex (FDD). One end of the filter 31 is connected to a terminal 60d (third terminal) of the switch 60 (first switch). The filter 31 is used for reception in Band C (C-Rx). The filter 31 may have a pass band including a transmission band of Band C for FDD. Alternatively, Band C may be a band for TDD. In this case, the filter 31 may have a pass band including Band C.

The filter 32 is an example of a fourth filter, and has a pass band including a reception band (downlink operation band) of Band D (fourth band) for FDD. One end of the filter 32 is connected to the terminal 60d (third terminal) of the switch 60 (first switch). The filter 32 is used for reception in Band D (D-Rx). The filter 32 may have a pass band including a transmission band of Band D for FDD. Alternatively, Band D may be a band for TDD. In this case, the filter 32 may have a pass band including Band D.

In the present disclosure, Bands A, B, C, and D each mean a frequency band defined in advance, for a communication system constructed by using a radio access technology (RAT), by a standardizing body or the like (for example, 3rd Generation Partnership Project (3GPP, registered trademark), Institute of Electrical and Electronics Engineers (IEEE), or the like). The communication system may be, but is not limited to, a Long Term Evolution (LTE) system, a 5th Generation New Radio (5G NR) system, a Wireless Local Area Network (WLAN) system, or the like, for example.

The power amplifier 40 is an example of a first power amplifier. An input end of the power amplifier 40 is connected to the RF input terminal 110. An output end of the power amplifier 40 is connected to a terminal 61c (sixth terminal) of the switch 61 (second switch). The power amplifier 40 is capable of amplifying, by using electric power supplied from a power source, transmission signals of Bands A and B supplied from the RFIC 3 via the RF input terminal 110.

The power amplifier 40 can be constituted by a heterojunction bipolar transistor (HBT) and can be manufactured by using a semiconductor material. The semiconductor material may be, for example, silicon-germanium (SiGe) or gallium arsenide (GaAs). The amplifier transistor of the power amplifier 40 is not limited to an HBT. For example, the power amplifier 40 may be constituted by a high electron mobility transistor (HEMT) or a metal-semiconductor field effect transistor (MESFET). In this case, the semiconductor material may be gallium nitride (GaN) or silicon carbide (SiC).

The low-noise amplifier 51 is an example of a first low-noise amplifier. An input end of the low-noise amplifier 51 is connected to a terminal 61d (seventh terminal) of the switch 61 (second switch). An output end of the low-noise amplifier 51 is connected to the RF output terminal 120. The low-noise amplifier 51 is capable of amplifying, by using electric power supplied from a power source, a reception signal of Band A passed through the filter 10.

The low-noise amplifier 52 is an example of a second low-noise amplifier. An input end of the low-noise amplifier 52 is connected to a terminal 61e (eighth terminal) of the switch 61 (second switch). An output end of the low-noise amplifier 52 is connected to the RF output terminal 130. The low-noise amplifier 52 is capable of amplifying, by using electric power supplied from a power source, a reception signal of Band B passed through the filter 20.

Each of the low-noise amplifiers 51 and 52 can be constituted by a field effect transistor (FET) and can be manufactured by using a semiconductor material. The semiconductor material may be, for example, a silicon single crystal, GaN, or SiC. The amplifier transistor of each of the low-noise amplifiers 51 and 52 is not limited to an FET. For example, a part or the entirety of each of the low-noise amplifiers 51 and 52 may be constituted by a bipolar transistor.

The switch 60 is an example of a first switch and is connected between the antenna terminal 100 and the filters 10, 20, 31, and 32. To be specific, the switch 60 includes the terminals 60a, 60b, 60c, and 60d. The terminal 60a is an example of a first antenna connection terminal and is connected to the antenna terminal 100. The terminal 60b is an example of a first terminal and is connected to only the filter 10 among the filters including an acoustic wave resonator. The terminal 60c is an example of a second terminal and is connected to only the filter 20 among the filters including an acoustic wave resonator. The terminal 60d is an example of a third terminal and is connected to the filters 31 and 32.

With this connection configuration, the switch 60 is capable of, for example, based on a control signal from the RFIC 3, switching between connection and disconnection between the terminal 60a and the terminal 60b, switching between connection and disconnection between the terminal 60a and the terminal 60c, and switching between connection and disconnection between the terminal 60a and the terminal 60d. The switch 60 is constituted by, for example, a single pole 3 throw (SP3T) switch circuit.

The switch 61 is an example of a second switch and is connected between the filters 10 and 20 and a set of the power amplifier 40 and the low-noise amplifiers 51 and 52. To be specific, the switch 61 includes the terminals 61a, 61b, 61c, 61d, and 61e. The terminal 61a is an example of a fourth terminal and is connected to the filter 10. The terminal 61b is an example of a fifth terminal and is connected to the filter 20. The terminal 61c is an example of a sixth terminal and is connected to the output end of the power amplifier 40. The terminal 61d is an example of a seventh terminal and is connected to the input end of the low-noise amplifier 51. The terminal 61e is an example of an eighth terminal and is connected to the input end of the low-noise amplifier 52.

With this connection configuration, the switch 61 is capable of, for example, based on a control signal from the RFIC 3, exclusively connecting the terminal 61a to the terminals 61c and 61d and exclusively connecting the terminal 61b to the terminals 61c and 61e. The switch 61 is constituted by, for example, a double pole 3 throw (DP3T) switch circuit.

With the above-described configuration, the RF circuit 1 is capable of executing simultaneous Rx/Tx of simultaneously transferring one of a transmission signal and a reception signal of Band A for TDD and the other of a transmission signal and a reception signal of Band B for TDD.

### 1.3 Communication Bands

Now, a description will be given of the relationships between the communication bands used in the RF circuit 1 and the communication device 4 according to the present embodiment.

Band A and Band B are both communication bands for TDD, and constitute a band combination capable of simultaneously transferring a transmission signal of Band A and a reception signal of Band B or simultaneously transferring a reception signal of Band A and a transmission signal of Band B. That is, Band A and Band B constitute a band combination capable of simultaneously transferring one of a transmission signal and a reception signal of Band A and the other of a transmission signal and a reception signal of Band B.

That is, Band A and Band B constitute a band combination capable of executing simultaneous Rx/Tx of simultaneously performing transmission and reception by combining two TDD bands.

Band C and Band D constitute a band combination capable of simultaneously transferring a signal of Band C and a signal of Band D. Furthermore, Bands A, B, C, and D constitute a band combination capable of simultaneously transferring at least one of a signal of Band A and a signal of Band B and at least one of a signal of Band C and a signal of Band D.

The combination of Band A and Band B may be a combination of Band 40 (2300-2400 MHz) for LTE or n40 (2300-2400 MHz) for 5G NR and Band 41 (2496-2690 MHz) for LTE or n41 (2496-2690 MHz) for 5G NR. Instead of Band 40 for LTE or n40 for 5G NR, Band 39 (1880-1920 MHz) for LTE or n39 (1880-1920 MHz) for 5G NR may be used. The combination of Band A and Band B is not limited to the above.

The combination of Band C and Band D may be a combination of two of Band 1, Band 3, Band 25, Band 30, Band 32, and Band 66 for LTE, or a combination of two of n1, n3, n25, n30, n32, and n66 for 5G NR.

In an existing technique, to support a mode of performing simultaneous transmission or simultaneous reception by using two TDD bands, a first filter whose pass band is one of the TDD bands and a second filter whose pass band is the other of the TDD bands are optimized.

On the other hand, in the case of executing simultaneous Rx/Tx by using two TDD bands (one TDD band and the other TDD band), it is desired that the impedance for the other TDD band in the first filter and the impedance for the one TDD band in the second filter be open so that degradation of reception sensitivity of the other TDD band resulting from leakage of a transmission signal of the one TDD band is reduced. Here, for example, when the first filter is connected to one switch terminal in common with a filter whose pass band is a band different from the two TDD bands, priority is to be given to making the impedance for the foregoing different band open in the first filter. Accordingly, it is not possible to sufficiently make the impedance for the other TDD band open in the first filter, and attenuation in the other TDD band is not sufficiently secured.

In contrast, in the RF circuit 1 according to the present embodiment, the terminal 60b of the switch 60 is connected to only the filter 10 among the filters including an acoustic wave resonator, and the terminal 60c of the switch 60 is connected to only the filter 20 among the filters including an acoustic wave resonator. In other words, the filter 10 is not connected to a terminal of the switch 60 in common with a filter whose pass band is the foregoing different band, but is solely connected to the terminal 60b. In addition, the filter 20 is not connected to a terminal of the switch 60 in common with a filter whose pass band is the foregoing different band, but is solely connected to the terminal 60c.

Accordingly, the highest priority can be given to making the impedance for Band B on the other side open in the filter 10, and the highest priority can be given to making the impedance for Band A on the other side open in the filter 20. This makes it possible to provide the RF circuit 1 and the communication device 4 with improved quality of a transmission signal and improved reception sensitivity in simultaneous Rx/Tx using Band A and Band B.

### 1.4 Connection Manners in RF Circuit 1

Next, a plurality of connection manners in the RF circuit 1 will be described.

### 1.4.1 First Connection Manner

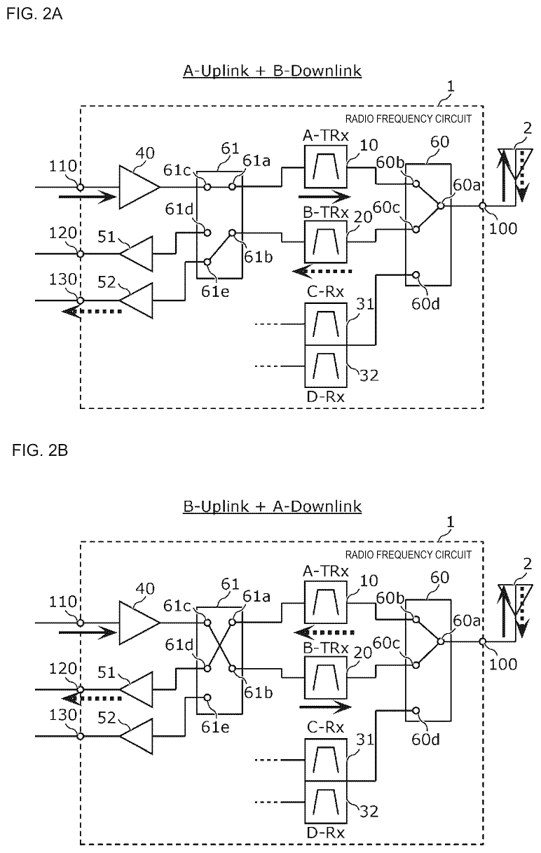

First, a first connection manner will be described with reference to FIG. 2A. FIG. 2A is a diagram illustrating a first connection manner in the RF circuit 1 according to the first embodiment. In the drawings referenced hereinafter, a solid-line arrow indicates a flow of a transmission signal, and a broken-line arrow indicates a flow of a reception signal.

In the first connection manner, a transmission signal of Band A and a reception signal of Band B can be simultaneously transferred (A-Uplink+B-Downlink). That is, the first connection manner is a connection manner for simultaneous Rx/Tx. As illustrated in FIG. 2A, in the first connection manner, the terminal 60a and the terminal 60b are connected to each other, the terminal 60a and the terminal 60c are connected to each other, the terminal 61a and the terminal 61c are connected to each other, and the terminal 61b and the terminal 61e are connected to each other.

Accordingly, a transmission signal of Band A is transferred from the RFIC 3 to the antenna 2 via the RF input terminal 110, the power amplifier 40, the switch 61, the filter 10, the switch 60, and the antenna terminal 100. A reception signal of Band B is transferred from the antenna 2 to the RFIC 3 via the antenna terminal 100, the switch 60, the filter 20, the switch 61, the low-noise amplifier 52, and the RF output terminal 130.

### 1.4.2 Second Connection Manner

Next, a second connection manner will be described with reference to FIG. 2B. FIG. 2B is a diagram illustrating a second connection manner in the RF circuit 1 according to the first embodiment.

In the second connection manner, a reception signal of Band A and a transmission signal of Band B can be simultaneously transferred (B-Uplink+A-Downlink). That is, the second connection manner is a connection manner for simultaneous Rx/Tx. As illustrated in FIG. 2B, in the second connection manner, the terminal 60a and the terminal 60b are connected to each other, the terminal 60a and the terminal 60c are connected to each other, the terminal 61a and the terminal 61d are connected to each other, and the terminal 61b and the terminal 61c are connected to each other.

Accordingly, a transmission signal of Band B is transferred from the RFIC 3 to the antenna 2 via the RF input terminal 110, the power amplifier 40, the switch 61, the filter 20, the switch 60, and the antenna terminal 100. A reception signal of Band A is transferred from the antenna 2 to the RFIC 3 via the antenna terminal 100, the switch 60, the filter 10, the switch 61, the low-noise amplifier 51, and the RF output terminal 120.

### 1.4.3 Third Connection Manner

Next, a third connection manner will be described. In the third connection manner, a reception signal of Band C and a reception signal of Band D can be simultaneously transferred. In the third connection manner, the terminal 60a and the terminal 60d are connected to each other.

Accordingly, a reception signal of Band C is transferred from the antenna 2 to the RFIC 3 via the antenna terminal 100, the switch 60, and the filter 31. A reception signal of Band D is transferred from the antenna 2 to the RFIC 3 via the antenna terminal 100, the switch 60, and the filter 32.

### 1.4.4 Fourth Connection Manner

Next, a fourth connection manner will be described. In the fourth connection manner, a transmission signal of Band A, a reception signal of Band C, and a reception signal of Band D can be simultaneously transferred. In the fourth connection manner, the terminal 60a and the terminal 60b are connected to each other, the terminal 60a and the terminal 60d are connected to each other, and the terminal 61a and the terminal 61c are connected to each other.

Accordingly, a transmission signal of Band A is transferred from the RFIC 3 to the antenna 2 via the RF input terminal 110, the power amplifier 40, the switch 61, the filter 10, the switch 60, and the antenna terminal 100. A reception signal of Band C is transferred from the antenna 2 to the RFIC 3 via the antenna terminal 100, the switch 60, and the filter 31. A reception signal of Band D is transferred from the antenna 2 to the RFIC 3 via the antenna terminal 100, the switch 60, and the filter 32.

### 1.4.5 Fifth Connection Manner

Next, a fifth connection manner will be described. In the fifth connection manner, a reception signal of Band B, a reception signal of Band C, and a reception signal of Band D can be simultaneously transferred. In the fifth connection manner, the terminal 60a and the terminal 60c are connected to each other, the terminal 60a and the terminal 60d are connected to each other, and the terminal 61b and the terminal 61e are connected to each other.

Accordingly, a reception signal of Band B is transferred from the antenna 2 to the RFIC 3 via the antenna terminal 100, the switch 60, the filter 20, the switch 61, the low-noise amplifier 52, and the RF output terminal 130. A reception signal of Band C is transferred from the antenna 2 to the RFIC 3 via the antenna terminal 100, the switch 60, and the filter 31. A reception signal of Band D is transferred from the antenna 2 to the RFIC 3 via the antenna terminal 100, the switch 60, and the filter 32.

### 1.5 Circuit Configuration of RF Circuit 1A According to First Modification

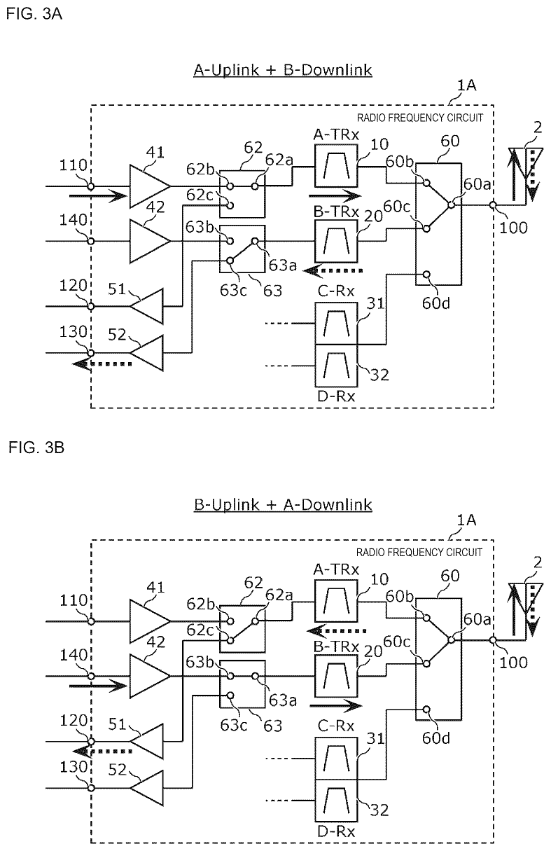

Next, the circuit configuration of an RF circuit 1A according to a first modification will be described. FIG. 3A is a diagram illustrating a first connection manner in the RF circuit 1A according to the first modification of the first embodiment. FIG. 3B is a diagram illustrating a second connection manner in the RF circuit 1A according to the first modification of the first embodiment. As illustrated in FIG. 3A and FIG. 3B, the RF circuit 1A includes the filters 10, 20, 31, and 32, the switch 60, switches 62 and 63, power amplifiers 41 and 42, the low-noise amplifiers 51 and 52, the antenna terminal 100, the RF input terminal 110, an RF input terminal 140, and the RF output terminals 120 and 130. The RF circuit 1A according to the present modification is different from the RF circuit 1 according to the first embodiment in that a transmission signal of Band A and a transmission signal of Band B are not amplified by the common power amplifier 40 but are respectively amplified by the power amplifiers 41 and 42. Hereinafter, the RF circuit 1A according to the present modification will be described, focusing on the configuration different from that of the RF circuit 1 according to the first embodiment and omitting a description of the configuration that is the same as in the RF circuit 1.

The RF input terminal 110 is connected to the RFIC 3 and the power amplifier 41 and serves as a terminal for receiving a transmission signal from the RFIC 3. The RF input terminal 140 is connected to the RFIC 3 and the power amplifier 42 and serves as a terminal for receiving a transmission signal from the RFIC 3.

The filter 10 is an example of a first filter, has a pass band including Band A (first band) for TDD, and includes an acoustic wave resonator. One end of the filter 10 is connected to the terminal 60b (first terminal) of the switch 60 (first switch), and the other end of the filter 10 is connected to a terminal 62a (fourth terminal) of the switch 62 (second switch). The filter 10 is used for transmission and reception in Band A (A-TRx).

The filter 20 is an example of a second filter, has a pass band including Band B (second band) for TDD, and includes an acoustic wave resonator. One end of the filter 20 is connected to the terminal 60c (second terminal) of the switch 60 (first switch), and the other end of the filter 20 is connected to a terminal 63a (seventh terminal) of the switch 63 (third switch). The filter 20 is used for transmission and reception in Band B (B-TRx).

The power amplifier 41 is an example of a first power amplifier. An input end of the power amplifier 41 is connected to the RF input terminal 110. An output end of the power amplifier 41 is connected to a terminal 62b (fifth terminal) of the switch 62 (second switch). The power amplifier 41 is capable of amplifying, by using electric power supplied from a power source, a transmission signal of Band A supplied from the RFIC 3 via the RF input terminal 110.

The power amplifier 42 is an example of a second power amplifier. An input end of the power amplifier 42 is connected to the RF input terminal 140. An output end of the power amplifier 42 is connected to a terminal 63b (eighth terminal) of the switch 63 (third switch). The power amplifier 42 is capable of amplifying, by using electric power supplied from a power source, a transmission signal of Band B supplied from the RFIC 3 via the RF input terminal 140.

The low-noise amplifier 51 is an example of a first low-noise amplifier. The input end of the low-noise amplifier 51 is connected to a terminal 62c (sixth terminal) of the switch 62 (second switch). The output end of the low-noise amplifier 51 is connected to the RF output terminal 120.

The low-noise amplifier 52 is an example of a second low-noise amplifier. The input end of the low-noise amplifier 52 is connected to a terminal 63c (ninth terminal) of the switch 63 (third switch). The output end of the low-noise amplifier 52 is connected to the RF output terminal 130.

The switch 62 is an example of a second switch and is connected between the filter 10 and a set of the power amplifier 41 and the low-noise amplifier 51. To be specific, the switch 62 includes the terminals 62a, 62b, and 62c. The terminal 62a is an example of a fourth terminal and is connected to the filter 10. The terminal 62b is an example of a fifth terminal and is connected to the output end of the power amplifier 41. The terminal 62c is an example of a sixth terminal and is connected to the input end of the low-noise amplifier 51.

The switch 63 is an example of a third switch and is connected between the filter 20 and a set of the power amplifier 42 and the low-noise amplifier 52. To be specific, the switch 63 includes the terminals 63a, 63b, and 63c. The terminal 63a is an example of a seventh terminal and is connected to the filter 20. The terminal 63b is an example of an eighth terminal and is connected to the output end of the power amplifier 42. The terminal 63c is an example of a ninth terminal and is connected to the input end of the low-noise amplifier 52.

With this connection configuration, the switch 62 is capable of, for example, based on a control signal from the RFIC 3, exclusively connecting the terminal 62a to the terminals 62b and 62c. In addition, the switch 63 is capable of, for example, based on a control signal from the RFIC 3, exclusively connecting the terminal 63a to the terminals 63b and 63c. The switches 62 and 63 are each constituted by, for example, a single pole double throw (SPDT) switch circuit.

With the above-described configuration, the RF circuit 1A is capable of executing simultaneous Rx/Tx of simultaneously transferring one of a transmission signal and a reception signal of Band A for TDD and the other of a transmission signal and a reception signal of Band B for TDD.

### 1.6 Connection Manners in RF Circuit 1A

Next, a plurality of connection manners in the RF circuit 1A will be described.

### 1.6.1 First Connection Manner

First, a first connection manner will be described with reference to FIG. 3A. In the first connection manner, a transmission signal of Band A and a reception signal of Band B can be simultaneously transferred (A-Uplink+B-Downlink). That is, the first connection manner is a connection manner for simultaneous Rx/Tx. As illustrated in FIG. 3A, in the first connection manner, the terminal 60a and the terminal 60b are connected to each other, the terminal 60a and the terminal 60c are connected to each other, the terminal 62a and the terminal 62b are connected to each other, and the terminal 63a and the terminal 63c are connected to each other.

Accordingly, a transmission signal of Band A is transferred from the RFIC 3 to the antenna 2 via the RF input terminal 110, the power amplifier 41, the switch 62, the filter 10, the switch 60, and the antenna terminal 100. A reception signal of Band B is transferred from the antenna 2 to the RFIC 3 via the antenna terminal 100, the switch 60, the filter 20, the switch 63, the low-noise amplifier 52, and the RF output terminal 130.

### 1.6.2 Second Connection Manner

Next, a second connection manner will be described with reference to FIG. 3B. In the second connection manner, a reception signal of Band A and a transmission signal of Band B can be simultaneously transferred (B-Uplink+A-Downlink). That is, the second connection manner is a connection manner for simultaneous Rx/Tx. As illustrated in FIG. 3B, in the second connection manner, the terminal 60a and the terminal 60b are connected to each other, the terminal 60a and the terminal 60c are connected to each other, the terminal 62a and the terminal 62c are connected to each other, and the terminal 63a and the terminal 63b are connected to each other.

Accordingly, a transmission signal of Band B is transferred from the RFIC 3 to the antenna 2 via the RF input terminal 140, the power amplifier 42, the switch 63, the filter 20, the switch 60, and the antenna terminal 100. A reception signal of Band A is transferred from the antenna 2 to the RFIC 3 via the antenna terminal 100, the switch 60, the filter 10, the switch 62, the low-noise amplifier 51, and the RF output terminal 120.

### 1.6.3 Third Connection Manner

Next, a third connection manner will be described. In the third connection manner, a reception signal of Band C and a reception signal of Band D can be simultaneously transferred. In the third connection manner, the terminal 60a and the terminal 60d are connected to each other.

Accordingly, a reception signal of Band C is transferred from the antenna 2 to the RFIC 3 via the antenna terminal 100, the switch 60, and the filter 31. A reception signal of Band D is transferred from the antenna 2 to the RFIC 3 via the antenna terminal 100, the switch 60, and the filter 32.

### 1.6.4 Fourth Connection Manner

Next, a fourth connection manner will be described. In the fourth connection manner, a transmission signal of Band A, a reception signal of Band C, and a reception signal of Band D can be simultaneously transferred. In the fourth connection manner, the terminal 60a and the terminal 60b are connected to each other, the terminal 60a and the terminal 60d are connected to each other, and the terminal 62a and the terminal 62b are connected to each other.

Accordingly, a transmission signal of Band A is transferred from the RFIC 3 to the antenna 2 via the RF input terminal 110, the power amplifier 41, the switch 62, the filter 10, the switch 60, and the antenna terminal 100. A reception signal of Band C is transferred from the antenna 2 to the RFIC 3 via the antenna terminal 100, the switch 60, and the filter 31. A reception signal of Band D is transferred from the antenna 2 to the RFIC 3 via the antenna terminal 100, the switch 60, and the filter 32.

### 1.6.5 Fifth Connection Manner

Next, a fifth connection manner will be described. In the fifth connection manner, a reception signal of Band B, a reception signal of Band C, and a reception signal of Band D can be simultaneously transferred. In the fifth connection manner, the terminal 60a and the terminal 60c are connected to each other, the terminal 60a and the terminal 60d are connected to each other, and the terminal 63a and the terminal 63c are connected to each other.

Accordingly, a reception signal of Band B is transferred from the antenna 2 to the RFIC 3 via the antenna terminal 100, the switch 60, the filter 20, the switch 63, the low-noise amplifier 52, and the RF output terminal 130. A reception signal of Band C is transferred from the antenna 2 to the RFIC 3 via the antenna terminal 100, the switch 60, and the filter 31. A reception signal of Band D is transferred from the antenna 2 to the RFIC 3 via the antenna terminal 100, the switch 60, and the filter 32.

In the RF circuit 1A according to the present modification, the terminal 60b of the switch 60 is connected to only the filter 10 among the filters including an acoustic wave resonator, and the terminal 60c of the switch 60 is connected to only the filter 20 among the filters including an acoustic wave resonator. In other words, the filter 10 is not connected to a terminal of the switch 60 in common with a filter whose pass band is different, but is solely connected to the terminal 60b. The filter 20 is not connected to a terminal of the switch 60 in common with a filter whose pass band is different, but is solely connected to the terminal 60c.

Accordingly, the highest priority can be given to making the impedance for Band B on the other side open in the filter 10, and the highest priority can be given to making the impedance for Band A on the other side open in the filter 20. This makes it possible to provide the RF circuit 1A with improved quality of a transmission signal and improved reception sensitivity in simultaneous Rx/Tx using Band A and Band B.

### 1.7 Circuit Configuration of RF Circuit 1B According to Second Modification

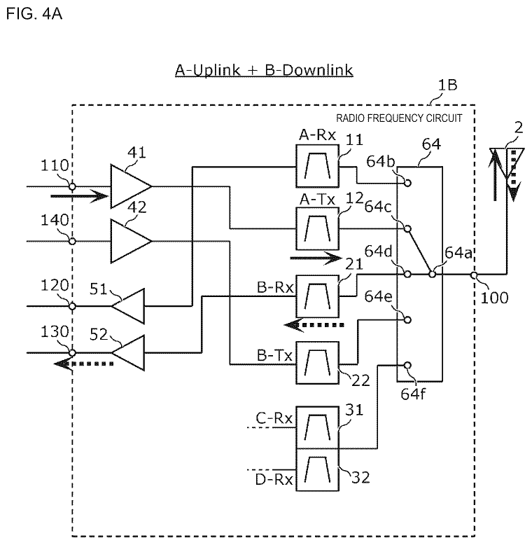

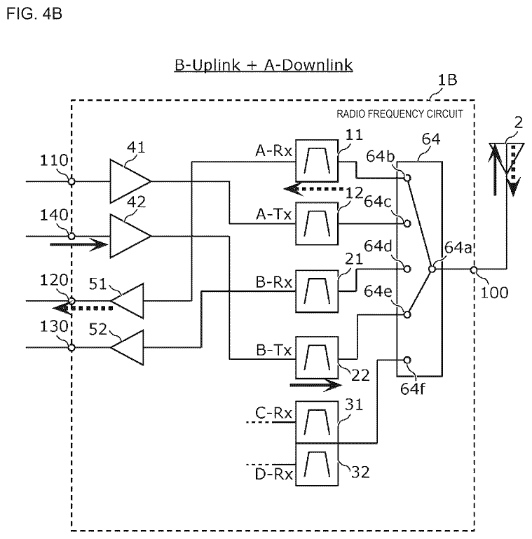

Next, the circuit configuration of an RF circuit 1B according to a second modification will be described. FIG. 4A is a diagram illustrating a first connection manner in the RF circuit 1B according to the second modification of the first embodiment. FIG. 4B is a diagram illustrating a second connection manner in the RF circuit 1B according to the second modification of the first embodiment. As illustrated in FIG. 4A and FIG. 4B, the RF circuit 1B includes filters 11, 12, 21, and 22, the filters 31 and 32, a switch 64, the power amplifiers 41 and 42, the low-noise amplifiers 51 and 52, the antenna terminal 100, the RF input terminals 110 and 140, and the RF output terminals 120 and 130. The RF circuit 1B according to the present modification is different from the RF circuit 1A according to the first modification in that the filter 11 for reception and the filter 12 for transmission for Band A are provided instead of the filter 10 and that the filter 21 for reception and the filter 22 for transmission for Band B are provided instead of the filter 20. Hereinafter, the RF circuit 1B according to the present modification will be described, focusing on the configuration different from that of the RF circuit 1A according to the first modification and omitting a description of the configuration that is the same as in the RF circuit 1A.

The filter 11 is an example of a fifth filter, has a pass band including Band A (first band) for TDD, and includes an acoustic wave resonator. One end of the filter 11 is connected to a terminal 64b (tenth terminal) of the switch 64 (first switch), and the other end of the filter 11 is connected to the input end of the low-noise amplifier 51. The filter 11 is used for reception in Band A (A-Rx).

The filter 12 is an example of a first filter, has a pass band including Band A (first band) for TDD, and includes an acoustic wave resonator. One end of the filter 12 is connected to a terminal 64c (first terminal) of the switch 64 (first switch), and the other end of the filter 12 is connected to the output end of the power amplifier 41. The filter 12 is used for transmission in Band A (A-Tx).

The filter 21 is an example of a second filter, has a pass band including Band B (second band) for TDD, and includes an acoustic wave resonator. One end of the filter 21 is connected to a terminal 64d (second terminal) of the switch 64 (first switch), and the other end of the filter 21 is connected to the input end of the low-noise amplifier 52. The filter 21 is used for reception in Band B (B-Rx).

The filter 22 is an example of a sixth filter, has a pass band including Band B (second band) for TDD, and includes an acoustic wave resonator. One end of the filter 22 is connected to a terminal 64e (eleventh terminal) of the switch 64 (first switch), and the other end of the filter 22 is connected to the output end of the power amplifier 42. The filter 22 is used for transmission in Band B (B-Tx).

The power amplifier 41 is an example of a first power amplifier. The input end of the power amplifier 41 is connected to the RF input terminal 110, and the output end thereof is connected to the filter 12. The power amplifier 41 is capable of amplifying, by using electric power supplied from a power source, a transmission signal of Band A supplied from the RFIC 3 via the RF input terminal 110.

The power amplifier 42 is an example of a second power amplifier. The input end of the power amplifier 42 is connected to the RF input terminal 140, and the output end thereof is connected to the filter 22. The power amplifier 42 is capable of amplifying, by using electric power supplied from a power source, a transmission signal of Band B supplied from the RFIC 3 via the RF input terminal 140.

The low-noise amplifier 51 is an example of a first low-noise amplifier. The input end of the low-noise amplifier 51 is connected to the filter 11, and the output end thereof is connected to the RF output terminal 120.

The low-noise amplifier 52 is an example of a second low-noise amplifier. The input end of the low-noise amplifier 52 is connected to the filter 21, and the output end thereof is connected to the RF output terminal 130.

The switch 64 is an example of a first switch and is connected between the antenna terminal 100 and the filters 11, 12, 21, 22, 31, and 32. To be specific, the switch 64 includes terminals 64a, 64b, 64c, 64d, 64e, and 64f. The terminal 64a is an example of a first antenna connection terminal and is connected to the antenna terminal 100. The terminal 64b is an example of a tenth terminal and is connected to only the filter 11 among the filters including an acoustic wave resonator. The terminal 64c is an example of a first terminal and is connected to only the filter 12 among the filters including an acoustic wave resonator. The terminal 64d is an example of a second terminal and is connected to only the filter 21 among the filters including an acoustic wave resonator. The terminal 64e is an example of an eleventh terminal and is connected to only the filter 22 among the filters including an acoustic wave resonator. The terminal 64f is an example of a third terminal and is connected to the filters 31 and 32.

With this connection configuration, the switch 64 is capable of, for example, based on a control signal from the RFIC 3, switching between connection and disconnection between the terminal 64a and the terminal 64b, switching between connection and disconnection between the terminal 64a and the terminal 64c, switching between connection and disconnection between the terminal 64a and the terminal 64d, switching between connection and disconnection between the terminal 64a and the terminal 64e, and switching between connection and disconnection between the terminal 64a and the terminal 64f. The switch 64 is constituted by, for example, a single pole 5 throw (SP5T) switch circuit.

With the above-described configuration, the RF circuit 1B is capable of executing simultaneous Rx/Tx of simultaneously transferring one of a transmission signal and a reception signal of Band A for TDD and the other of a transmission signal and a reception signal of Band B for TDD.

### 1.8 Connection Manners in RF Circuit 1B

Next, a plurality of connection manners in the RF circuit 1B will be described.

### 1.8.1 First Connection Manner

First, a first connection manner will be described with reference to FIG. 4A. In the first connection manner, a transmission signal of Band A and a reception signal of Band B can be simultaneously transferred (A-Uplink+B-Downlink). That is, the first connection manner is a connection manner for simultaneous Rx/Tx. As illustrated in FIG. 4A, in the first connection manner, the terminal 64a and the terminal 64c are connected to each other, and the terminal 64a and the terminal 64d are connected to each other.

Accordingly, a transmission signal of Band A is transferred from the RFIC 3 to the antenna 2 via the RF input terminal 110, the power amplifier 41, the filter 12, the switch 64, and the antenna terminal 100. A reception signal of Band B is transferred from the antenna 2 to the RFIC 3 via the antenna terminal 100, the switch 64, the filter 21, the low-noise amplifier 52, and the RF output terminal 130.

### 1.8.2 Second Connection Manner

Next, a second connection manner will be described with reference to FIG. 4B. In the second connection manner, a reception signal of Band A and a transmission signal of Band B can be simultaneously transferred (B-Uplink+A-Downlink). That is, the second connection manner is a connection manner for simultaneous Rx/Tx. As illustrated in FIG. 4B, in the second connection manner, the terminal 64a and the terminal 64b are connected to each other, and the terminal 64a and the terminal 64e are connected to each other.

Accordingly, a transmission signal of Band B is transferred from the RFIC 3 to the antenna 2 via the RF input terminal 140, the power amplifier 42, the filter 22, the switch 64, and the antenna terminal 100. A reception signal of Band A is transferred from the antenna 2 to the RFIC 3 via the antenna terminal 100, the switch 64, the filter 11, the low-noise amplifier 51, and the RF output terminal 120.

### 1.8.3 Third Connection Manner

Next, a third connection manner will be described. In the third connection manner, a reception signal of Band C and a reception signal of Band D can be simultaneously transferred. In the third connection manner, the terminal 64a and the terminal 64f are connected to each other.

Accordingly, a reception signal of Band C is transferred from the antenna 2 to the RFIC 3 via the antenna terminal 100, the switch 64, and the filter 31. A reception signal of Band D is transferred from the antenna 2 to the RFIC 3 via the antenna terminal 100, the switch 64, and the filter 32.

### 1.8.4 Fourth Connection Manner

Next, a fourth connection manner will be described. In the fourth connection manner, a transmission signal of Band A, a reception signal of Band C, and a reception signal of Band D can be simultaneously transferred. In the fourth connection manner, the terminal 64a and the terminal 64c are connected to each other, and the terminal 64a and the terminal 64f are connected to each other.

Accordingly, a transmission signal of Band A is transferred from the RFIC 3 to the antenna 2 via the RF input terminal 110, the power amplifier 41, the filter 12, the switch 64, and the antenna terminal 100. A reception signal of Band C is transferred from the antenna 2 to the RFIC 3 via the antenna terminal 100, the switch 64, and the filter 31. A reception signal of Band D is transferred from the antenna 2 to the RFIC 3 via the antenna terminal 100, the switch 64, and the filter 32.

### 1.8.5 Fifth Connection Manner

Next, a fifth connection manner will be described. In the fifth connection manner, a reception signal of Band B, a reception signal of Band C, and a reception signal of Band D can be simultaneously transferred. In the fifth connection manner, the terminal 64a and the terminal 64d are connected to each other, and the terminal 64a and the terminal 64f are connected to each other.

Accordingly, a reception signal of Band B is transferred from the antenna 2 to the RFIC 3 via the antenna terminal 100, the switch 64, the filter 21, the low-noise amplifier 52, and the RF output terminal 130. A reception signal of Band C is transferred from the antenna 2 to the RFIC 3 via the antenna terminal 100, the switch 64, and the filter 31. A reception signal of Band D is transferred from the antenna 2 to the RFIC 3 via the antenna terminal 100, the switch 64, and the filter 32.

In the RF circuit 1B according to the present modification, the terminal 64b of the switch 64 is connected to only the filter 11 among the filters including an acoustic wave resonator, the terminal 64c of the switch 64 is connected to only the filter 12 among the filters including an acoustic wave resonator, the terminal 64d of the switch 64 is connected to only the filter 21 among the filters including an acoustic wave resonator, and the terminal 64e of the switch 64 is connected to only the filter 22 among the filters including an acoustic wave resonator. In other words, the filter 11 is not connected to a terminal of the switch 64 in common with a filter whose pass band is different, but is solely connected to the terminal 64b. The filter 12 is not connected to a terminal of the switch 64 in common with a filter whose pass band is different, but is solely connected to the terminal 64c. The filter 21 is not connected to a terminal of the switch 64 in common with a filter whose pass band is different, but is solely connected to the terminal 64d. The filter 22 is not connected to a terminal of the switch 64 in common with a filter whose pass band is different, but is solely connected to the terminal 64e.

Accordingly, the highest priority can be given to making the impedance for Band B on the other side open in the filters 11 and 12, and the highest priority can be given to making the impedance for Band A on the other side open in the filters 21 and 22. This makes it possible to provide the RF circuit 1B with improved quality of a transmission signal and improved reception sensitivity in simultaneous Rx/Tx using Band A and Band B.

### 1.9 Circuit Configuration of RF Circuit 1C According to Third Modification

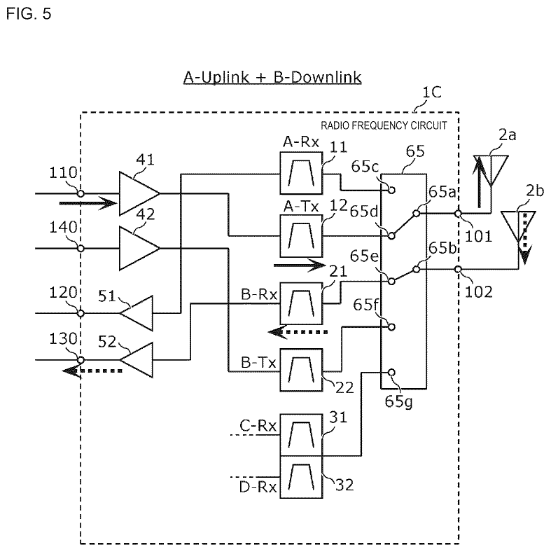

Next, the circuit configuration of an RF circuit 1C according to a third modification will be described. FIG. 5 is a diagram illustrating a first connection manner in the RF circuit 1C according to the third modification of the first embodiment. As illustrated in FIG. 5, the RF circuit 1C includes the filters 11, 12, 21, 22, 31, and 32, a switch 65, the power amplifiers 41 and 42, the low-noise amplifiers 51 and 52, antenna terminals 101 and 102, the RF input terminals 110 and 140, and the RF output terminals 120 and 130. The RF circuit 1C according to the present modification is different from the RF circuit 1B according to the second modification in that the RF circuit 1C has a configuration of being connectable to two antennas. Hereinafter, the RF circuit 1C according to the present modification will be described, focusing on the configuration different from that of the RF circuit 1B according to the second modification and omitting a description of the configuration that is the same as in the RF circuit 1B.

The antenna terminal 101 is connected to an antenna 2a (first antenna) and a terminal 65a (first antenna connection terminal) of the switch 65 (first switch). The antenna terminal 102 is connected to an antenna 2b (second antenna) and a terminal 65b (second antenna connection terminal) of the switch 65 (first switch).

The switch 65 is an example of a first switch and is connected between the antenna terminals 101 and 102 and the filters 11, 12, 21, 22, 31, and 32. To be specific, the switch 65 includes terminals 65a, 65b, 65c, 65d, 65e, 65f, and 65g. The terminal 65a is an example of a first antenna connection terminal and is connected to the antenna terminal 101. The terminal 65b is an example of a second antenna connection terminal and is connected to the antenna terminal 102. The terminal 65c is an example of a tenth terminal and is connected to only the filter 11 among the filters including an acoustic wave resonator. The terminal 65d is an example of a first terminal and is connected to only the filter 12 among the filters including an acoustic wave resonator. The terminal 65e is an example of a second terminal and is connected to only the filter 21 among the filters including an acoustic wave resonator. The terminal 65f is an example of an eleventh terminal and is connected to only the filter 22 among the filters including an acoustic wave resonator. The terminal 65g is an example of a third terminal and is connected to the filters 31 and 32.

With this connection configuration, the switch 65 is capable of, for example, based on a control signal from the RFIC 3, switching between connection and disconnection between the terminal 65a and the terminals 65c to 65g and switching between connection and disconnection between the terminal 65b and the terminals 65c to 65g. The switch 65 is constituted by, for example, a double pole 5 throw (DP5T) switch circuit.

With the above-described configuration, the RF circuit 1C is capable of executing simultaneous Rx/Tx of simultaneously transferring one of a transmission signal and a reception signal of Band A for TDD and the other of a transmission signal and a reception signal of Band B for TDD.

### 1.10 Connection Manners in RF Circuit 1C

Next, a first connection manner among a plurality of connection manners in the RF circuit 1C will be described. A description of the other connection manners is omitted.

### 1.10.1 First Connection Manner

The first connection manner will be described with reference to FIG. 5. In the first connection manner, a transmission signal of Band A and a reception signal of Band B can be simultaneously transferred (A-Uplink+B-Downlink). That is, the first connection manner is a connection manner for simultaneous Rx/Tx. As illustrated in FIG. 5, in the first connection manner, the terminal 65a and the terminal 65d are connected to each other, and the terminal 65b and the terminal 65e are connected to each other.

Accordingly, a transmission signal of Band A is transferred from the RFIC 3 to the antenna 2a via the RF input terminal 110, the power amplifier 41, the filter 12, the switch 65, and the antenna terminal 101. A reception signal of Band B is transferred from the antenna 2b to the RFIC 3 via the antenna terminal 102, the switch 65, the filter 21, the low-noise amplifier 52, and the RF output terminal 130.

In the RF circuit 1C according to the present modification, as compared with the RF circuit 1B according to the second modification, a signal of Band A and a signal of Band B are simultaneously transferred via different antennas, and thus the isolation between a transmission signal and a reception signal in simultaneous Rx/Tx using Band A and Band B can be further improved.

### 1.11 Circuit Configuration of RF Circuit 1D According to Fourth Modification

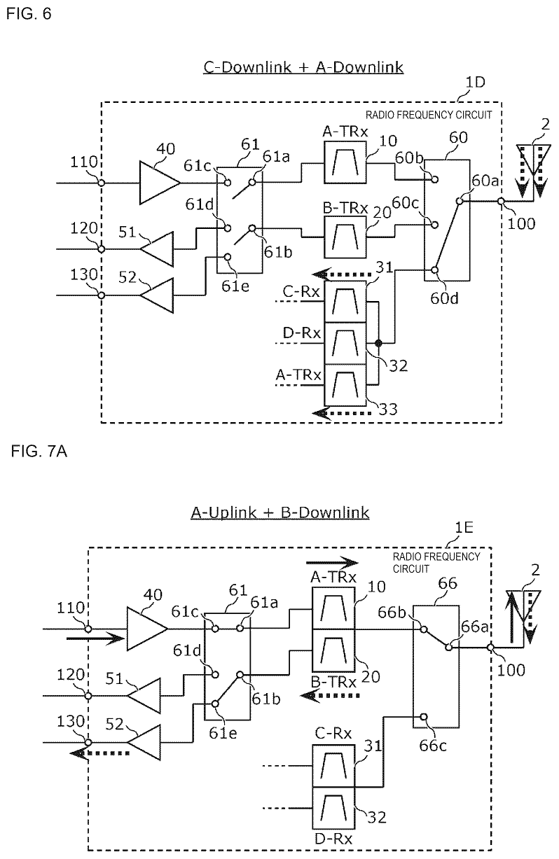

Next, the circuit configuration of an RF circuit 1D according to a fourth modification will be described. FIG. 6 is a diagram illustrating a third connection manner in the RF circuit 1D according to the fourth modification of the first embodiment. As illustrated in FIG. 6, the RF circuit 1D includes the filters 10, 20, 31, and 32, a filter 33, the switches 60 and 61, the power amplifier 40, the low-noise amplifiers 51 and 52, the antenna terminal 100, the RF input terminal 110, and the RF output terminals 120 and 130. The RF circuit 1D according to the present modification is different from the RF circuit 1 according to the first embodiment in that the filter 33 is further included. Hereinafter, the RF circuit 1D according to the present modification will be described, focusing on the configuration different from that of the RF circuit 1 according to the first embodiment and omitting a description of the configuration that is the same as in the RF circuit 1.

The filter 33 is an example of a seventh filter, has a pass band including Band A (first band) for TDD, and includes an acoustic wave resonator. One end of the filter 33 is connected to the terminal 60d (third terminal) of the switch 60 (first switch). The filter 33 is used for transmission and reception in Band A (A-TRx).

### 1.12 Connection Manners in RF Circuit 1D

Next, a plurality of connection manners in the RF circuit 1D will be described.

A first connection manner in the case of simultaneously transferring a transmission signal of Band A and a reception signal of Band B (A-Uplink+B-Downlink) is the same as the first connection manner in the RF circuit 1 according to the first embodiment.

A second connection manner in the case of simultaneously transferring a reception signal of Band A and a transmission signal of Band B (B-Uplink+A-Downlink) is the same as the second connection manner in the RF circuit 1 according to the first embodiment.

A third connection manner in the case of simultaneously transferring a reception signal of Band C and a reception signal of Band D is the same as the third connection manner in the RF circuit 1 according to the first embodiment.

In the case of simultaneously transferring a reception signal of Band A and a reception signal of Band C and not simultaneously transferring a transmission signal of Band B, the terminal 60a and the terminal 60b are not connected to each other, the terminal 60a and the terminal 60c are not connected to each other, and the terminal 60a and the terminal 60d are connected to each other, as illustrated in FIG. 6.

Accordingly, a reception signal of Band A is transferred from the antenna 2 to the RFIC 3 via the antenna terminal 100, the switch 60, and the filter 33. A reception signal of Band C is transferred from the antenna 2 to the RFIC 3 via the antenna terminal 100, the switch 60, and the filter 31.

In the RF circuit 1D according to the present modification, in the case of executing simultaneous Rx/Tx of Band A and Band B, the filter 10 solely connected to the terminal 60b and the filter 20 solely connected to the terminal 60c are used, and thus the quality of a transmission signal and reception sensitivity can be improved in simultaneous Rx/Tx using Band A and Band B.

In the case of simultaneously transferring one of a signal of Band A and a signal of Band B and at least one of a signal of Band C and a signal of Band D, the filter 33 connected to the terminal 60d is used together with the filters 31 and 32, and thus a reception signal can be transferred with low loss.

### 1.13 Advantageous Effects and the Like

As described above, the RF circuit 1 according to the present embodiment includes the filter 10 that has a pass band including Band A for TDD and that includes an acoustic wave resonator, the filter 20 that has a pass band including Band B for TDD and that includes an acoustic wave resonator, the filter 31 that has a pass band including a transmission band or a reception band of Band C, the filter 32 that has a pass band including a transmission band or a reception band of Band D, and the switch 60 including the terminals 60a to 60d. Band A and Band B constitute a band combination capable of simultaneously transferring one of a transmission signal and a reception signal of Band A and the other of a transmission signal and a reception signal of Band B. Band C and Band D constitute a band combination capable of simultaneously transferring a signal of Band C and a signal of Band D. Bands A to D constitute a band combination capable of simultaneously transferring at least one of a signal of Band A and a signal of Band B and at least one of a signal of Band C and a signal of Band D. The terminal 60b is connected to only the filter 10 among the filters including an acoustic wave resonator. The terminal 60c is connected to only the filter 20 among the filters including an acoustic wave resonator. The terminal 60d is connected to the filters 31 and 32.

Accordingly, the filter 10 is not connected to a terminal of the switch 60 in common with a filter whose pass band is different, but is solely connected to the terminal 60b. The filter 20 is not connected to a terminal of the switch 60 in common with a filter whose pass band is different, but is solely connected to the terminal 60c. Accordingly, the highest priority can be given to making the impedance for Band B on the other side open in the filter 10, and the highest priority can be given to making the impedance for Band A on the other side open in the filter 20. This makes it possible to provide the RF circuit 1 with improved quality of a transmission signal and improved reception sensitivity in simultaneous Rx/Tx using Band A and Band B.

For example, the RF circuit 1 further includes the switch 61 including the terminals 61a to 61e, the power amplifier 40, and the low-noise amplifiers 51 and 52. The terminal 61a is connected to the filter 10. The terminal 61b is connected to the filter 20. The terminal 61c is connected to the power amplifier 40. The terminal 61d is connected to the low-noise amplifier 51. The terminal 61e is connected to the low-noise amplifier 52.

Accordingly, one of a transmission signal and a reception signal can be allowed to pass through the filter 10 and the other of a transmission signal and a reception signal can be allowed to pass through the filter 20 at the same time.

For example, in the RF circuit 1, in the case of simultaneously transferring a transmission signal of Band A and a reception signal of Band B, the terminal 60a and the terminal 60b are connected to each other, the terminal 60a and the terminal 60c are connected to each other, the terminal 61a and the terminal 61c are connected to each other, and the terminal 61b and the terminal 61e are connected to each other. In the case of simultaneously transferring a signal of Band C and a signal of Band D, the terminal 60a and the terminal 60d are connected to each other.

Accordingly, in the case of simultaneously transferring a transmission signal of Band A and a reception signal of Band B, the highest priority is given to the isolation between Band A and Band B, and thus the transmission signal of Band A and the reception signal of Band B can be transferred with low loss. In the case of simultaneously transferring a signal of Band C and a signal of Band D, the highest priority is given to the isolation between Band C and Band D, and thus the signal of Band C and the signal of Band D can be transferred with low loss.

For example, in the RF circuit 1, in the case of simultaneously transferring a transmission signal of Band A and at least one of a signal of Band C and a signal of Band D, the terminal 60a and the terminal 60b are connected to each other, the terminal 60a and the terminal 60d are connected to each other, and the terminal 61a and the terminal 61c are connected to each other. In the case of simultaneously transferring a reception signal of Band B and at least one of a signal of Band C and a signal of Band D, the terminal 60a and the terminal 60c are connected to each other, the terminal 60a and the terminal 60d are connected to each other, and the terminal 61b and the terminal 61e are connected to each other.

Accordingly, in the case of simultaneously transferring a transmission signal of Band A and at least one of a signal of Band C and a signal of Band D, the isolation between the transmission signal of Band A and the at least one of the signal of Band C and the signal of Band D can be secured, and thus the transmission signal of Band A and the at least one of the signal of Band C and the signal of Band D can be transferred with low loss. In addition, in the case of simultaneously transferring a reception signal of Band B and at least one of a signal of Band C and a signal of Band D, the isolation between the reception signal of Band B and the at least one of the signal of Band C and the signal of Band D can be secured, and thus the reception signal of Band B and the at least one of the signal of Band C and the signal of Band D can be transferred with low loss.

For example, the RF circuit 1A according to the first modification includes the filters 10, 20, 31, and 32; the switch 60; the switch 62 including the terminals 62a, 62b, and 62c; the switch 63 including the terminals 63a, 63b, and 63c; the power amplifiers 41 and 42; and the low-noise amplifiers 51 and 52. The terminal 62a is connected to the filter 10. The terminal 62b is connected to the power amplifier 41. The terminal 62c is connected to the low-noise amplifier 51. The terminal 63a is connected to the filter 20. The terminal 63b is connected to the power amplifier 42. The terminal 63c is connected to the low-noise amplifier 52.

Accordingly, with the two switches 62 and 63 that switch between transmission and reception, one of a transmission signal and a reception signal can be allowed to pass through the filter 10 and the other of a transmission signal and a reception signal can be allowed to pass through the filter 20 at the same time.

For example, in the RF circuit 1A according to the first modification, in the case of simultaneously transferring a transmission signal of Band A and a reception signal of Band B, the terminal 60a and the terminal 60b are connected to each other, the terminal 60a and the terminal 60c are connected to each other, the terminal 62a and the terminal 62b are connected to each other, and the terminal 63a and the terminal 63c are connected to each other. In the case of simultaneously transferring a signal of Band C and a signal of Band D, the terminal 60a and the terminal 60d are connected to each other.

Accordingly, in the case of simultaneously transferring a transmission signal of Band A and a reception signal of Band B, the highest priority is given to the isolation between Band A and Band B, and thus the transmission signal of Band A and the reception signal of Band B can be transferred with low loss. In the case of simultaneously transferring a signal of Band C and a signal of Band D, the highest priority is given to the isolation between Band C and Band D, and thus the signal of Band C and the signal of Band D can be transferred with low loss.

For example, in the RF circuit 1A according to the first modification, in the case of simultaneously transferring a transmission signal of Band A and at least one of a signal of Band C and a signal of Band D, the terminal 60a and the terminal 60b are connected to each other, the terminal 60a and the terminal 60d are connected to each other, and the terminal 62a and the terminal 62b are connected to each other. In the case of simultaneously transferring a reception signal of Band B and at least one of a signal of Band C and a signal of Band D, the terminal 60a and the terminal 60c are connected to each other, the terminal 60a and the terminal 60d are connected to each other, and the terminal 63a and the terminal 63c are connected to each other.

Accordingly, in the case of simultaneously transferring a transmission signal of Band A and at least one of a signal of Band C and a signal of Band D, the isolation between the transmission signal of Band A and the at least one of the signal of Band C and the signal of Band D can be secured, and thus the transmission signal of Band A and the at least one of the signal of Band C and the signal of Band D can be transferred with low loss. In addition, in the case of simultaneously transferring a reception signal of Band B and at least one of a signal of Band C and a signal of Band D, the isolation between the reception signal of Band B and the at least one of the signal of Band C and the signal of Band D can be secured, and thus the reception signal of Band B and the at least one of the signal of Band C and the signal of Band D can be transferred with low loss.

For example, the RF circuit 1B according to the second modification includes the filters 11 and 12 each having a pass band including Band A for TDD and each including an acoustic wave resonator, the filters 21 and 22 each having a pass band including Band B for TDD and each including an acoustic wave resonator, the filter 31 having a pass band including a transmission band or a reception band of Band C, the filter 32 having a pass band including a transmission band or a reception band of Band D, and the switch 64 including the terminals 64a to 64f. The terminal 64b is connected to only the filter 11 among the filters including an acoustic wave resonator. The terminal 64c is connected to only the filter 12 among the filters including an acoustic wave resonator. The terminal 64d is connected to only the filter 21 among the filters including an acoustic wave resonator. The terminal 64e is connected to only the filter 22 among the filters including an acoustic wave resonator. The terminal 64f is connected to the filters 31 and 32.

Accordingly, each of the filters 11, 12, 21, and 22 is not connected to a terminal of the switch 64 in common with a filter whose pass band is different, but is solely connected. Accordingly, the highest priority can be given to making the impedance for Band B on the other side open in the filters 11 and 12, and the highest priority can be given to making the impedance for Band A on the other side open in the filters 21 and 22. This makes it possible to provide the RF circuit 1B with improved quality of a transmission signal and improved reception sensitivity in simultaneous Rx/Tx using Band A and Band B.

For example, in the RF circuit 1B, in the case of simultaneously transferring a transmission signal of Band A and a reception signal of Band B, the terminal 64a and the terminal 64c are connected to each other, and the terminal 64a and the terminal 64d are connected to each other. In the case of simultaneously transferring a reception signal of Band A and a transmission signal of Band B, the terminal 64a and the terminal 64b are connected to each other, and the terminal 64a and the terminal 64e are connected to each other. In the case of simultaneously transferring a signal of Band C and a signal of Band D, the terminal 64a and the terminal 64f are connected to each other.

Accordingly, in the case of simultaneously transferring a transmission signal of Band A and a reception signal of Band B, the highest priority is given to the isolation between Band A and Band B, and thus the transmission signal of Band A and the reception signal of Band B can be transferred with low loss. In the case of simultaneously transferring a reception signal of Band A and a transmission signal of Band B, the highest priority is given to the isolation between Band A and Band B, and thus the reception signal of Band A and the transmission signal of Band B can be transferred with low loss. In the case of simultaneously transferring a signal of Band C and a signal of Band D, the highest priority is given to the isolation between Band C and Band D, and thus the signal of Band C and the signal of Band D can be transferred with low loss.

For example, in the RF circuit 1B, in the case of simultaneously transferring a transmission signal of Band A and at least one of a signal of Band C and a signal of Band D, the terminal 64a and the terminal 64c are connected to each other, and the terminal 64a and the terminal 64f are connected to each other. In the case of simultaneously transferring a reception signal of Band B and at least one of a signal of Band C and a signal of Band D, the terminal 64a and the terminal 64d are connected to each other, and the terminal 64a and the terminal 64f are connected to each other. In the case of simultaneously transferring a reception signal of Band A and at least one of a signal of Band C and a signal of Band D, the terminal 64a and the terminal 64b are connected to each other, and the terminal 64a and the terminal 64f are connected to each other. In the case of simultaneously transferring a transmission signal of Band B and at least one of a signal of Band C and a signal of Band D, the terminal 64a and the terminal 64e are connected to each other, and the terminal 64a and the terminal 64f are connected to each other.

Accordingly, in the case of simultaneously transferring a transmission signal or a reception signal of Band A and at least one of a signal of Band C and a signal of Band D, the isolation between the transmission signal or the reception signal of Band A and the at least one of the signal of Band C and the signal of Band D can be secured, and thus the transmission signal or the reception signal of Band A and the at least one of the signal of Band C and the signal of Band D can be transferred with low loss. In the case of simultaneously transferring a transmission signal or a reception signal of Band B and at least one of a signal of Band C and a signal of Band D, the isolation between the transmission signal or the reception signal of Band B and the at least one of the signal of Band C and the signal of Band D can be secured, and thus the transmission signal or the reception signal of Band B and the at least one of the signal of Band C and the signal of Band D can be transferred with low loss.

For example, the RF circuit 1C according to the third modification includes the filters 11, 12, 21, 22, 31, and 32; and the switch 65 including the terminals 65a to 65g. The terminal 65a is connected to the antenna 2a. The terminal 65b is connected to the antenna 2b. The terminal 65c is connected to only the filter 11 among the filters including an acoustic wave resonator. The terminal 65d is connected to only the filter 12 among the filters including an acoustic wave resonator. The terminal 65e is connected to only the filter 21 among the filters including an acoustic wave resonator. The terminal 65f is connected to only the filter 22 among the filters including an acoustic wave resonator. The terminal 65g is connected to the filters 31 and 32. In the case of simultaneously transferring one of a transmission signal and a reception signal of Band A and the other of a transmission signal and a reception signal of Band B, the terminal 65a and the terminal 65d are connected to each other, and the terminal 65b and the terminal 65e are connected to each other.

Accordingly, as compared with the RF circuit 1B according to the second modification, a signal of Band A and a signal of Band B are simultaneously transferred via different antennas, and thus the isolation between a transmission signal and a reception signal in simultaneous Rx/Tx can be further improved.

For example, the RF circuit 1D according to the fourth modification includes the filter 10 that has a pass band including Band A for TDD and that includes an acoustic wave resonator, the filter 20 that has a pass band including Band B for TDD and that includes an acoustic wave resonator, the filter 31 that has a pass band including a transmission band or a reception band of Band C, the filter 32 that has a pass band including a transmission band or a reception band of Band D, the filter 33 that has a pass band including Band A for TDD and that includes an acoustic wave resonator, and the switch 60 including the terminals 60a to 60d. The terminal 60b is connected to only the filter 10 among the filters including an acoustic wave resonator. The terminal 60c is connected to only the filter 20 among the filters including an acoustic wave resonator. The terminal 60d is connected to the filters 31, 32, and 33. In the case of simultaneously transferring one of a transmission signal and a reception signal of Band A and the other of a transmission signal and a reception signal of Band B, the terminal 60a and the terminal 60b are connected to each other, the terminal 60a and the terminal 60c are connected to each other, and the terminal 60a and the terminal 60d are not connected to each other. In the case of simultaneously transferring at least one of a signal of Band C and a signal of Band D and one of a transmission signal and a reception signal of Band A, the terminal 60a and the terminal 60b are not connected to each other, the terminal 60a and the terminal 60c are not connected to each other, and the terminal 60a and the terminal 60d are connected to each other.

Accordingly, in the case of executing simultaneous Rx/Tx of Band A and Band B, the filter 10 solely connected to the terminal 60b and the filter 20 solely connected to the terminal 60c are used, and thus the quality of a transmission signal and reception sensitivity can be improved in simultaneous Rx/Tx using Band A and Band B. In the case of simultaneously transferring a signal of either Band A or Band B and a signal of at least one of Band C and Band D, the filter 33 connected to the terminal 60d is used together with the filters 31 and 32, and thus the signals can be transferred with low loss.

For example, in the RF circuits 1 and 1A to 1D, a combination of Band A and Band B is a combination of Band 40 for LTE or n40 for 5G NR and Band 41 for LTE or n41 for 5G NR, or a combination of Band 39 for LTE or n39 for 5G NR and Band 41 for LTE or n41 for 5G NR.

Accordingly, signal quality in simultaneous Rx/Tx can be improved in an LTE or 5G NR communication network.

For example, in the RF circuits 1 and 1A to 1D, a combination of Band C and Band D is a combination of two of Band 1, Band 3, Band 25, Band 30, Band 32, and Band 66 for LTE, or a combination of two of n1, n3, n25, n30, n32, and n66 for 5G NR.

The communication device 4 according to the present embodiment includes the RFIC 3 configured to process an RF signal, and the RF circuit 1 configured to transfer the RF signal between the RFIC 3 and the antenna 2.

Accordingly, advantageous effects similar to those of the RF circuit 1 can be implemented in the communication device 4.

### Second Embodiment

The present embodiment is different from the first embodiment mainly in that a plurality of filters each having a pass band including Band A or Band B used in simultaneous Rx/Tx are configured to be commonly connected to one switch terminal. Hereinafter, the present embodiment will be described with a focus on differences from the first embodiment with reference to the drawings.

### 2.1 Circuit Configuration of RF Circuit 1E

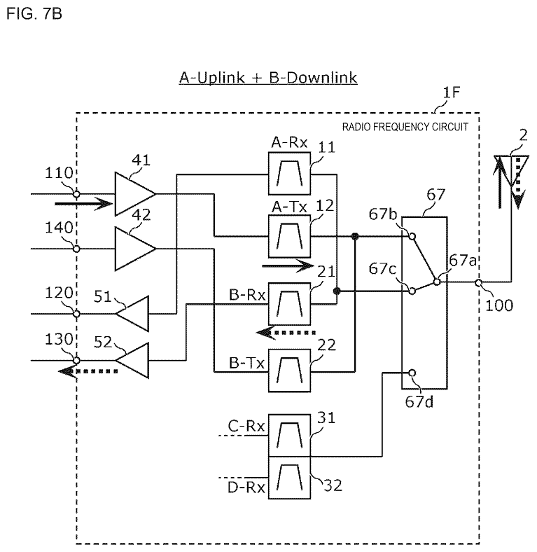

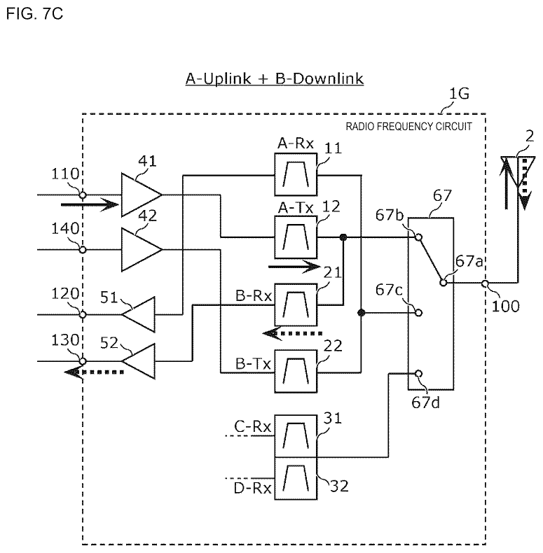

FIG. 7A is a diagram illustrating a first connection manner in an RF circuit 1E according to the second embodiment. As illustrated in FIG. 7A, the RF circuit 1E includes the filters 10, 20, 31, and 32, a switch 66, the switch 61, the power amplifier 40, the low-noise amplifiers 51 and 52, the antenna terminal 100, the RF input terminal 110, and the RF output terminals 120 and 130. The RF circuit 1E according to the present embodiment is different from the RF circuit 1 according to the first embodiment in the configuration of the switch 66 and the connection configuration between the individual filters and the switch 66. Hereinafter, the RF circuit 1E according to the present embodiment will be described, focusing on the configuration different from that of the RF circuit 1 according to the first embodiment and omitting a description of the configuration that is the same as in the RF circuit 1.

The antenna terminal 100 is connected to the antenna 2 and a terminal 66a of the switch 66.

The filter 10 is an example of a first filter, has a pass band including Band A (first band) for TDD, and includes an acoustic wave resonator. One end of the filter 10 is connected to a terminal 66b (first terminal) of the switch 66 (first switch), and the other end of the filter 10 is connected to the terminal 61a (fourth terminal) of the switch 61 (second switch). The filter 10 is used for transmission and reception in Band A (A-TRx).

The filter 20 is an example of a second filter, has a pass band including Band B (second band) for TDD, and includes an acoustic wave resonator. One end of the filter 20 is connected to the terminal 66b (first terminal) of the switch 66 (first switch), and the other end of the filter 20 is connected to the terminal 61b (fifth terminal) of the switch 61 (second switch). The filter 20 is used for transmission and reception in Band B (B-TRx).

The filters 10 and 20 are each constituted by a SAW filter, a BAW filter, or a combination thereof.

The filter 31 is an example of a third filter, and has a pass band including a reception band (downlink operation band) of Band C (third band) for FDD. One end of the filter 31 is connected to a terminal 66c (second terminal) of the switch 66 (first switch). The filter 31 is used for reception in Band C (C-Rx). The filter 31 may have a pass band including a transmission band of Band C for FDD. Alternatively, Band C may be a band for TDD. In this case, the filter 31 may have a pass band including Band C.

The filter 32 is an example of a fourth filter, and has a pass band including a reception band (downlink operation band) of Band D (fourth band) for FDD. One end of the filter 32 is connected to the terminal 66c (second terminal) of the switch 66 (first switch). The filter 32 is used for reception in Band D (D-Rx). The filter 32 may have a pass band including a transmission band of Band D for FDD. Alternatively, Band D may be a band for TDD. In this case, the filter 32 may have a pass band including Band D.

The power amplifier 40 is an example of a first power amplifier. The input end of the power amplifier 40 is connected to the RF input terminal 110. The output end of the power amplifier 40 is connected to the terminal 61c (sixth terminal) of the switch 61 (second switch). The power amplifier 40 is capable of amplifying, by using electric power supplied from a power source, transmission signals of Bands A and B supplied from the RFIC 3 via the RF input terminal 110.

The low-noise amplifier 51 is an example of a first low-noise amplifier. The input end of the low-noise amplifier 51 is connected to the terminal 61d (seventh terminal) of the switch 61 (second switch). The output end of the low-noise amplifier 51 is connected to the RF output terminal 120. The low-noise amplifier 51 is capable of amplifying, by using electric power supplied from a power source, a reception signal of Band A passed through the filter 10.

The low-noise amplifier 52 is an example of a second low-noise amplifier. The input end of the low-noise amplifier 52 is connected to the terminal 61e (eighth terminal) of the switch 61 (second switch). The output end of the low-noise amplifier 52 is connected to the RF output terminal 130. The low-noise amplifier 52 is capable of amplifying, by using electric power supplied from a power source, a reception signal of Band B passed through the filter 20.

The switch 66 is an example of a first switch and is connected between the antenna terminal 100 and the filters 10, 20, 31, and 32. To be specific, the switch 66 includes the terminals 66a, 66b, and 66c. The terminal 66a is an example of a first antenna connection terminal and is connected to the antenna terminal 100. The terminal 66b is an example of a first terminal and is connected to only the filters 10 and 20 among the filters including an acoustic wave resonator. The terminal 66c is an example of a second terminal and is connected to the filters 31 and 32.

With this connection configuration, the switch 66 is capable of, for example, based on a control signal from the RFIC 3, switching between connection and disconnection between the terminal 66a and the terminal 66b and switching between connection and disconnection between the terminal 66a and the terminal 66c. The switch 66 is constituted by, for example, an SPDT switch circuit.

The switch 61 is an example of a second switch and is connected between the filters 10 and 20 and a set of the power amplifier 40 and the low-noise amplifiers 51 and 52.

Band A and Band B are both communication bands for TDD, and constitute a band combination capable of simultaneously transferring a transmission signal of Band A and a reception signal of Band B or simultaneously transferring a reception signal of Band A and a transmission signal of Band B. That is, Band A and Band B constitute a band combination capable of simultaneously transferring one of a transmission signal and a reception signal of Band A and the other of a transmission signal and a reception signal of Band B.

That is, Band A and Band B constitute a band combination capable of executing simultaneous Rx/Tx of simultaneously performing transmission and reception by combining two TDD bands.

Band C and Band D constitute a band combination capable of simultaneously transferring a signal of Band C and a signal of Band D. Furthermore, Bands A, B, C, and D constitute a band combination capable of simultaneously transferring at least one of a signal of Band A and a signal of Band B and at least one of a signal of Band C and a signal of Band D.

With the above-described configuration, the RF circuit 1E is capable of executing simultaneous Rx/Tx of simultaneously transferring one of a transmission signal and a reception signal of Band A for TDD and the other of a transmission signal and a reception signal of Band B for TDD.

In the RF circuit 1E according to the present embodiment, the terminal 66b of the switch 66 is connected to only the filters 10 and 20 among the filters including an acoustic wave resonator. In other words, the filters 10 and 20 are not connected to a terminal of the switch 66 in common with a filter whose pass band is a band different from Band A or Band B, but are connected to the terminal 66b.

Accordingly, the highest priority can be given to making the impedance for Band B on the other side open in the filter 10, and the highest priority can be given to making the impedance for Band A on the other side open in the filter 20. This makes it possible to provide the RF circuit 1E with improved quality of a transmission signal and improved reception sensitivity in simultaneous Rx/Tx using Band A and Band B.

### 2.2 Connection Manners in RF Circuit 1E

Next, a plurality of connection manners in the RF circuit 1E will be described.

### 2.2.1 First Connection Manner

First, a first connection manner will be described with reference to FIG. 7A. In the first connection manner, a transmission signal of Band A and a reception signal of Band B can be simultaneously transferred (A-Uplink+B-Downlink). That is, the first connection manner is a connection manner for simultaneous Rx/Tx. As illustrated in FIG. 7A, in the first connection manner, the terminal 66a and the terminal 66b are connected to each other, the terminal 61a and the terminal 61c are connected to each other, and the terminal 61b and the terminal 61e are connected to each other.

Accordingly, a transmission signal of Band A is transferred from the RFIC 3 to the antenna 2 via the RF input terminal 110, the power amplifier 40, the switch 61, the filter 10, the switch 66, and the antenna terminal 100. A reception signal of Band B is transferred from the antenna 2 to the RFIC 3 via the antenna terminal 100, the switch 66, the filter 20, the switch 61, the low-noise amplifier 52, and the RF output terminal 130.

### 2.2.2 Second Connection Manner

Next, a second connection manner will be described. In the second connection manner, a reception signal of Band A and a transmission signal of Band B can be simultaneously transferred (B-Uplink +A-Downlink). That is, the second connection manner is a connection manner for simultaneous Rx/Tx. In the second connection manner, the terminal 66a and the terminal 66b are connected to each other, the terminal 61a and the terminal 61d are connected to each other, and the terminal 61b and the terminal 61c are connected to each other.

Accordingly, a transmission signal of Band B is transferred from the RFIC 3 to the antenna 2 via the RF input terminal 110, the power amplifier 40, the switch 61, the filter 20, the switch 66, and the antenna terminal 100. A reception signal of Band A is transferred from the antenna 2 to the RFIC 3 via the antenna terminal 100, the switch 66, the filter 10, the switch 61, the low-noise amplifier 51, and the RF output terminal 120.

### 2.2.3 Third Connection Manner

Next, a third connection manner will be described. In the third connection manner, a reception signal of Band C and a reception signal of Band D can be simultaneously transferred. In the third connection manner, the terminal 66a and the terminal 66c are connected to each other.

Accordingly, a reception signal of Band C is transferred from the antenna 2 to the RFIC 3 via the antenna terminal 100, the switch 66, and the filter 31. A reception signal of Band D is transferred from the antenna 2 to the RFIC 3 via the antenna terminal 100, the switch 66, and the filter 32.

### 2.2.4 Fourth Connection Manner

Next, a fourth connection manner will be described. In the fourth connection manner, a transmission signal of Band A, a reception signal of Band C, and a reception signal of Band D can be simultaneously transferred. In the fourth connection manner, the terminal 66a and the terminal 66b are connected to each other, the terminal 66a and the terminal 66c are connected to each other, and the terminal 61a and the terminal 61c are connected to each other.

Accordingly, a transmission signal of Band A is transferred from the RFIC 3 to the antenna 2 via the RF input terminal 110, the power amplifier 40, the switch 61, the filter 10, the switch 66, and the antenna terminal 100. A reception signal of Band C is transferred from the antenna 2 to the RFIC 3 via the antenna terminal 100, the switch 66, and the filter 31. A reception signal of Band D is transferred from the antenna 2 to the RFIC 3 via the antenna terminal 100, the switch 66, and the filter 32.

### 2.2.5 Fifth Connection Manner

Next, a fifth connection manner will be described. In the fifth connection manner, a reception signal of Band B, a reception signal of Band C, and a reception signal of Band D can be simultaneously transferred. In the fifth connection manner, the terminal 66a and the terminal 66b are connected to each other, the terminal 66a and the terminal 66c are connected to each other, and the terminal 61b and the terminal 61e are connected to each other.

Accordingly, a reception signal of Band B is transferred from the antenna 2 to the RFIC 3 via the antenna terminal 100, the switch 66, the filter 20, the switch 61, the low-noise amplifier 52, and the RF output terminal 130. A reception signal of Band C is transferred from the antenna 2 to the RFIC 3 via the antenna terminal 100, the switch 66, and the filter 31. A reception signal of Band D is transferred from the antenna 2 to the RFIC 3 via the antenna terminal 100, the switch 66, and the filter 32.

### 2.3 Circuit Configuration of RF Circuit 1F According to Fifth Modification

Next, the circuit configuration of an RF circuit 1F according to a fifth modification of the second embodiment will be described. FIG. 7B is a diagram illustrating a first connection manner in the RF circuit 1F according to the fifth modification of the second embodiment. As illustrated in FIG. 7B, the RF circuit 1F includes the filters 11, 12, 21, 22, 31, and 32, a switch 67, the power amplifiers 41 and 42, the low-noise amplifiers 51 and 52, the antenna terminal 100, the RF input terminals 110 and 140, and the RF output terminals 120 and 130. The RF circuit 1F according to the present modification is different from the RF circuit 1B according to the second modification of the first embodiment in the configuration of the switch 67 and the connection configuration between the individual filters and the switch 67. Hereinafter, the RF circuit 1F according to the present modification will be described, focusing on the configuration different from that of the RF circuit 1B according to the second modification of the first embodiment and omitting a description of the configuration that is the same as in the RF circuit 1B.

The filter 11 is an example of a fifth filter, has a pass band including Band A (first band) for TDD, and includes an acoustic wave resonator. One end of the filter 11 is connected to a terminal 67c of the switch 67 (first switch), and the other end of the filter 11 is connected to the input end of the low-noise amplifier 51. The filter 11 is used for reception in Band A (A-Rx).

The filter 12 is an example of a first filter, has a pass band including Band A (first band) for TDD, and includes an acoustic wave resonator. One end of the filter 12 is connected to a terminal 67b (first terminal) of the switch 67 (first switch), and the other end of the filter 12 is connected to the output end of the power amplifier 41. The filter 12 is used for transmission in Band A (A-Tx).

The filter 21 is an example of a sixth filter, has a pass band including Band B (second band) for TDD, and includes an acoustic wave resonator. One end of the filter 21 is connected to the terminal 67c of the switch 67 (first switch), and the other end of the filter 21 is connected to the input end of the low-noise amplifier 52. The filter 21 is used for reception in Band B (B-Rx).

The filter 22 is an example of a second filter, has a pass band including Band B (second band) for TDD, and includes an acoustic wave resonator. One end of the filter 22 is connected to the terminal 67b (first terminal) of the switch 67 (first switch), and the other end of the filter 22 is connected to the output end of the power amplifier 42. The filter 22 is used for transmission in Band B (B-Tx).

The switch 67 is an example of a first switch and is connected between the antenna terminal 100 and the filters 11, 12, 21, 22, 31, and 32. To be specific, the switch 67 includes terminals 67a, 67b, 67c, and 67d. The terminal 67a is an example of a first antenna connection terminal and is connected to the antenna terminal 100. The terminal 67b is an example of a first terminal and is connected to only the filters 12 and 22 among the filters including an acoustic wave resonator. The terminal 67c is connected to only the filters 11 and 21 among the filters including an acoustic wave resonator. The terminal 67d is an example of a second terminal and is connected to the filters 31 and 32.

With this connection configuration, the switch 67 is capable of, for example, based on a control signal from the RFIC 3, switching between connection and disconnection between the terminal 67a and the terminals 67b to 67d. The switch 67 is constituted by, for example, an SP3T switch circuit.

With the above-described configuration, the RF circuit 1F is capable of executing simultaneous Rx/Tx of simultaneously transferring one of a transmission signal and a reception signal of Band A for TDD and the other of a transmission signal and a reception signal of Band B for TDD.

### 2.4 Connection Manners in RF Circuit 1F

Next, a plurality of connection manners in the RF circuit 1F will be described.

### 2.4.1 First Connection Manner

First, a first connection manner will be described with reference to FIG. 7B. In the first connection manner, a transmission signal of Band A and a reception signal of Band B can be simultaneously transferred (A-Uplink+B-Downlink). That is, the first connection manner is a connection manner for simultaneous Rx/Tx. As illustrated in FIG. 7B, in the first connection manner, the terminal 67a and the terminal 67b are connected to each other, and the terminal 67a and the terminal 67c are connected to each other.

Accordingly, a transmission signal of Band A is transferred from the RFIC 3 to the antenna 2 via the RF input terminal 110, the power amplifier 41, the filter 12, the switch 67, and the antenna terminal 100. A reception signal of Band B is transferred from the antenna 2 to the RFIC 3 via the antenna terminal 100, the switch 67, the filter 21, the low-noise amplifier 52, and the RF output terminal 130.

### 2.4.2 Second Connection Manner

Next, a second connection manner will be described. In the second connection manner, a reception signal of Band A and a transmission signal of Band B can be simultaneously transferred (B-Uplink+A-Downlink). That is, the second connection manner is a connection manner for simultaneous Rx/Tx. In the second connection manner, the terminal 67a and the terminal 67b are connected to each other, and the terminal 67a and the terminal 67c are connected to each other.

Accordingly, a transmission signal of Band B is transferred from the RFIC 3 to the antenna 2 via the RF input terminal 140, the power amplifier 42, the filter 22, the switch 67, and the antenna terminal 100. A reception signal of Band A is transferred from the antenna 2 to the RFIC 3 via the antenna terminal 100, the switch 67, the filter 11, the low-noise amplifier 51, and the RF output terminal 120.

### 2.4.3 Third Connection Manner

Next, a third connection manner will be described. In the third connection manner, a reception signal of Band C and a reception signal of Band D can be simultaneously transferred. In the third connection manner, the terminal 67a and the terminal 67d are connected to each other.

Accordingly, a reception signal of Band C is transferred from the antenna 2 to the RFIC 3 via the antenna terminal 100, the switch 67, and the filter 31. A reception signal of Band D is transferred from the antenna 2 to the RFIC 3 via the antenna terminal 100, the switch 67, and the filter 32.

### 2.4.4 Fourth Connection Manner

Next, a fourth connection manner will be described. In the fourth connection manner, a transmission signal of Band A, a reception signal of Band C, and a reception signal of Band D can be simultaneously transferred. In the fourth connection manner, the terminal 67a and the terminal 67b are connected to each other, and the terminal 67a and the terminal 67d are connected to each other.

Accordingly, a transmission signal of Band A is transferred from the RFIC 3 to the antenna 2 via the RF input terminal 110, the power amplifier 41, the filter 12, the switch 67, and the antenna terminal 100. A reception signal of Band C is transferred from the antenna 2 to the RFIC 3 via the antenna terminal 100, the switch 67, and the filter 31. A reception signal of Band D is transferred from the antenna 2 to the RFIC 3 via the antenna terminal 100, the switch 67, and the filter 32.

### 2.4.5 Fifth Connection Manner

Next, a fifth connection manner will be described. In the fifth connection manner, a reception signal of Band B, a reception signal of Band C, and a reception signal of Band D can be simultaneously transferred. In the fifth connection manner, the terminal 67a and the terminal 67c are connected to each other, and the terminal 67a and the terminal 67d are connected to each other.

Accordingly, a reception signal of Band B is transferred from the antenna 2 to the RFIC 3 via the antenna terminal 100, the switch 67, the filter 21, the low-noise amplifier 52, and the RF output terminal 130. A reception signal of Band C is transferred from the antenna 2 to the RFIC 3 via the antenna terminal 100, the switch 67, and the filter 31. A reception signal of Band D is transferred from the antenna 2 to the RFIC 3 via the antenna terminal 100, the switch 67, and the filter 32.

In the RF circuit 1F according to the present modification, the terminal 67b of the switch 67 is connected to only the filters 12 and 22 among the filters including an acoustic wave resonator. In other words, the filters 12 and 22 are not connected to a terminal of the switch 67 in common with a filter whose pass band is a band different from Band A or Band B, but are connected to the terminal 67b. The terminal 67c of the switch 67 is connected to only the filters 11 and 21 among the filters including an acoustic wave resonator. In other words, the filters 11 and 21 are not connected to a terminal of the switch 67 in common with a filter whose pass band is a band different from Band A or Band B, but are connected to the terminal 67c.

Accordingly, the highest priority can be given to making the impedance for Band B on the other side open in the filters 11 and 12, and the highest priority can be given to making the impedance for Band A on the other side open in the filters 21 and 22. This makes it possible to provide the RF circuit 1F with improved quality of a transmission signal and improved reception sensitivity in simultaneous Rx/Tx using Band A and Band B.

### 2.5 Circuit Configuration of RF Circuit 1G According to Sixth Modification

Next, the circuit configuration of an RF circuit 1G according to a sixth modification of the second embodiment will be described. FIG. 7C is a diagram illustrating a first connection manner in the RF circuit 1G according to the sixth modification of the second embodiment. As illustrated in FIG. 7C, the RF circuit 1G includes the filters 11, 12, 21, 22, 31, and 32, the switch 67, the power amplifiers 41 and 42, the low-noise amplifiers 51 and 52, the antenna terminal 100, the RF input terminals 110 and 140, and the RF output terminals 120 and 130. The RF circuit 1G according to the present modification is different from the RF circuit 1F according to the fifth modification of the second embodiment in the connection configuration between the individual filters and the switch 67. Hereinafter, the RF circuit 1G according to the present modification will be described, focusing on the configuration different from that of the RF circuit 1F according to the fifth modification of the second embodiment and omitting a description of the configuration that is the same as in the RF circuit 1F.

The filter 11 is an example of a fifth filter, has a pass band including Band A (first band) for TDD, and includes an acoustic wave resonator. One end of the filter 11 is connected to the terminal 67c of the switch 67 (first switch), and the other end of the filter 11 is connected to the input end of the low-noise amplifier 51. The filter 11 is used for reception in Band A (A-Rx).

The filter 12 is an example of a first filter, has a pass band including Band A (first band) for TDD, and includes an acoustic wave resonator. One end of the filter 12 is connected to the terminal 67b (first terminal) of the switch 67 (first switch), and the other end of the filter 12 is connected to the output end of the power amplifier 41. The filter 12 is used for transmission in Band A (A-Tx).

The filter 21 is an example of a second filter, has a pass band including Band B (second band) for TDD, and includes an acoustic wave resonator. One end of the filter 21 is connected to the terminal 67b (first terminal) of the switch 67 (first switch), and the other end of the filter 21 is connected to the input end of the low-noise amplifier 52. The filter 21 is used for reception in Band B (B-Rx).

The filter 22 is an example of a sixth filter, has a pass band including Band B (second band) for TDD, and includes an acoustic wave resonator. One end of the filter 22 is connected to the terminal 67c of the switch 67 (first switch), and the other end of the filter 22 is connected to the output end of the power amplifier 42. The filter 22 is used for transmission in Band B (B-Tx).

The switch 67 is an example of a first switch, and includes the terminals 67a, 67b, 67c, and 67d. The terminal 67a is an example of a first antenna connection terminal and is connected to the antenna terminal 100. The terminal 67b is an example of a first terminal and is connected to only the filters 12 and 21 among the filters including an acoustic wave resonator. The terminal 67c is connected to only the filters 11 and 22 among the filters including an acoustic wave resonator. The terminal 67d is an example of a second terminal and is connected to the filters 31 and 32.

With the above-described configuration, the RF circuit 1G is capable of executing simultaneous Rx/Tx of simultaneously transferring one of a transmission signal and a reception signal of Band A for TDD and the other of a transmission signal and a reception signal of Band B for TDD.

### 2.6 Connection Manners in RF Circuit 1G

Next, a plurality of connection manners in the RF circuit 1G will be described.

### 2.6.1 First Connection Manner

First, a first connection manner will be described with reference to FIG. 7C. In the first connection manner, a transmission signal of Band A and a reception signal of Band B can be simultaneously transferred (A-Uplink+B-Downlink). That is, the first connection manner is a connection manner for simultaneous Rx/Tx. As illustrated in FIG. 7C, in the first connection manner, the terminal 67a and the terminal 67b are connected to each other.

Accordingly, a transmission signal of Band A is transferred from the RFIC 3 to the antenna 2 via the RF input terminal 110, the power amplifier 41, the filter 12, the switch 67, and the antenna terminal 100. A reception signal of Band B is transferred from the antenna 2 to the RFIC 3 via the antenna terminal 100, the switch 67, the filter 21, the low-noise amplifier 52, and the RF output terminal 130.

### 2.6.2 Second Connection Manner

Next, a second connection manner will be described. In the second connection manner, a reception signal of Band A and a transmission signal of Band B can be simultaneously transferred (B-Uplink+A-Downlink). That is, the second connection manner is a connection manner for simultaneous Rx/Tx. In the second connection manner, the terminal 67a and the terminal 67c are connected to each other.

Accordingly, a transmission signal of Band B is transferred from the RFIC 3 to the antenna 2 via the RF input terminal 140, the power amplifier 42, the filter 22, the switch 67, and the antenna terminal 100. A reception signal of Band A is transferred from the antenna 2 to the RFIC 3 via the antenna terminal 100, the switch 67, the filter 11, the low-noise amplifier 51, and the RF output terminal 120.

### 2.6.3 Third Connection Manner

Next, a third connection manner will be described. In the third connection manner, a reception signal of Band C and a reception signal of Band D can be simultaneously transferred. In the third connection manner, the terminal 67a and the terminal 67d are connected to each other.

Accordingly, a reception signal of Band C is transferred from the antenna 2 to the RFIC 3 via the antenna terminal 100, the switch 67, and the filter 31. A reception signal of Band D is transferred from the antenna 2 to the RFIC 3 via the antenna terminal 100, the switch 67, and the filter 32.

### 2.6.4 Fourth Connection Manner

Next, a fourth connection manner will be described. In the fourth connection manner, a transmission signal of Band A, a reception signal of Band C, and a reception signal of Band D can be simultaneously transferred. In the fourth connection manner, the terminal 67a and the terminal 67b are connected to each other, and the terminal 67a and the terminal 67d are connected to each other.

Accordingly, a transmission signal of Band A is transferred from the RFIC 3 to the antenna 2 via the RF input terminal 110, the power amplifier 41, the filter 12, the switch 67, and the antenna terminal 100. A reception signal of Band C is transferred from the antenna 2 to the RFIC 3 via the antenna terminal 100, the switch 67, and the filter 31. A reception signal of Band D is transferred from the antenna 2 to the RFIC 3 via the antenna terminal 100, the switch 67, and the filter 32.

### 2.6.5 Fifth Connection Manner

Next, a fifth connection manner will be described. In the fifth connection manner, a reception signal of Band B, a reception signal of Band C, and a reception signal of Band D can be simultaneously transferred. In the fifth connection manner, the terminal 67a and the terminal 67b are connected to each other, and the terminal 67a and the terminal 67d are connected to each other.

Accordingly, a reception signal of Band B is transferred from the antenna 2 to the RFIC 3 via the antenna terminal 100, the switch 67, the filter 21, the low-noise amplifier 52, and the RF output terminal 130. A reception signal of Band C is transferred from the antenna 2 to the RFIC 3 via the antenna terminal 100, the switch 67, and the filter 31. A reception signal of Band D is transferred from the antenna 2 to the RFIC 3 via the antenna terminal 100, the switch 67, and the filter 32.

In the RF circuit 1G according to the present modification, the terminal 67b of the switch 67 is connected to only the filters 12 and 21 among the filters including an acoustic wave resonator. In other words, the filters 12 and 21 are not connected to a terminal of the switch 67 in common with a filter whose pass band is a band different from Band A or Band B, but are connected to the terminal 67b. The terminal 67c of the switch 67 is connected to only the filters 11 and 22 among the filters including an acoustic wave resonator. In other words, the filters 11 and 22 are not connected to a terminal of the switch 67 in common with a filter whose pass band is a band different from Band A or Band B, but are connected to the terminal 67c.

Accordingly, the highest priority can be given to making the impedance for Band B on the other side open in the filters 11 and 12, and the highest priority can be given to making the impedance for Band A on the other side open in the filters 21 and 22. This makes it possible to provide the RF circuit 1G with improved quality of a transmission signal and improved reception sensitivity in simultaneous Rx/Tx using Band A and Band B.

### 2.7 Advantageous Effects and the Like

As described above, the RF circuit 1E according to the present embodiment includes the filter 10 that has a pass band including Band A for TDD and that includes an acoustic wave resonator, the filter 20 that has a pass band including Band B for TDD and that includes an acoustic wave resonator, the filter 31 that has a pass band including a transmission band or a reception band of Band C, the filter 32 that has a pass band including a transmission band or a reception band of Band D, and the switch 66 including the terminals 66a to 66c. Band A and Band B constitute a band combination capable of simultaneously transferring one of a transmission signal and a reception signal of Band A and the other of a transmission signal and a reception signal of Band B. Band C and Band D constitute a band combination capable of simultaneously transferring a signal of Band C and a signal of Band D. Bands A to D constitute a band combination capable of simultaneously transferring at least one of a signal of Band A and a signal of Band B and at least one of a signal of Band C and a signal of Band D. The terminal 66b is connected to only the filters 10 and 20 among the filters including an acoustic wave resonator. The terminal 66c is connected to the filters 31 and 32.

Accordingly, the filters 10 and 20 are not connected to a terminal of the switch 66 in common with a filter whose pass band is a band different from Band A or Band B, but are connected to the terminal 66b. Accordingly, the highest priority can be given to making the impedance for Band B on the other side open in the filter 10, and the highest priority can be given to making the impedance for Band A on the other side open in the filter 20. This makes it possible to provide the RF circuit 1E with improved quality of a transmission signal and improved reception sensitivity in simultaneous Rx/Tx using Band A and Band B.

For example, in the RF circuits 1E to 1G, a combination of Band A and Band B is a combination of Band 40 for LTE or n40 for 5G NR and Band 41 for LTE or n41 for 5G NR, or a combination of Band 39 for LTE or n39 for 5G NR and Band 41 for LTE or n41 for 5G NR.

Accordingly, signal quality in simultaneous Rx/Tx can be improved in an LTE or 5G NR communication network.

For example, in the RF circuits 1E to 1G, a combination of Band C and Band D is a combination of two of Band 1, Band 3, Band 25, Band 30, Band 32, and Band 66 for LTE, or a combination of two of n1, n3, n25, n30, n32, and n66 for 5G NR.

### Other Embodiments

The RF circuit and the communication device according to the present disclosure have been described above based on embodiments and modifications. The RF circuit and the communication device according to the present disclosure are not limited to the above embodiments and modifications. Another embodiment implemented by combining any constituent elements in the above embodiments and modifications, modifications obtained by applying various changes conceived by those skilled in the art to the above embodiments and modifications without departing from the gist of the present disclosure, and various devices including any of the above-described RF circuits and communication devices are also included in the present disclosure.

For example, in the circuit configurations of the RF circuits and communication devices according to the above embodiments and modifications, another circuit element, wiring line, and the like may be inserted between individual circuit elements and paths connecting signal paths disclosed in the drawings.

In the above embodiments, cellular bands for 5G NR or LTE are used. In addition to or instead of the cellular bands for 5G NR or LTE, communication bands for another radio access technology may be used. For example, communication bands for a wireless local area network may be used.

Hereinafter, the features of the RF circuit and communication device described based on the above embodiments and modifications will be described.
<1> A radio frequency circuit including:
a first filter that has a pass band including a first band for time division duplex and that includes an acoustic wave resonator;
a second filter that has a pass band including a second band for time division duplex and that includes an acoustic wave resonator;
a third filter that has a pass band including a transmission band or a reception band of a third band;
a fourth filter that has a pass band including a transmission band or a reception band of a fourth band; and
a first switch including a first terminal, a second terminal, a third terminal, and a first antenna connection terminal, in which
the first band and the second band constitute a band combination capable of simultaneously transferring one of a transmission signal and a reception signal of the first band and another of a transmission signal and a reception signal of the second band,
the third band and the fourth band constitute a band combination capable of simultaneously transferring a signal of the third band and a signal of the fourth band,
the first band, the second band, the third band, and the fourth band constitute a band combination capable of simultaneously transferring at least one of a signal of the first band and a signal of the second band and at least one of a signal of the third band and a signal of the fourth band,
the first terminal is connected to only the first filter among the filters including an acoustic wave resonator,
the second terminal is connected to only the second filter among the filters including an acoustic wave resonator, and
the third terminal is connected to the third filter and the fourth filter.
<2> The radio frequency circuit according to <1>, further including:
a second switch including a fourth terminal, a fifth terminal, a sixth terminal, a seventh terminal, and an eighth terminal;
a first power amplifier; and
a first low-noise amplifier and a second low-noise amplifier, in which
the fourth terminal is connected to the first filter,
the fifth terminal is connected to the second filter,
the sixth terminal is connected to the first power amplifier,
the seventh terminal is connected to the first low-noise amplifier, and
the eighth terminal is connected to the second low-noise amplifier.
<3> The radio frequency circuit according to <2>, in which
the one of a transmission signal and a reception signal of the first band is a transmission signal of the first band,
the other of a transmission signal and a reception signal of the second band is a reception signal of the second band,
in a case of simultaneously transferring a transmission signal of the first band and a reception signal of the second band, the first antenna connection terminal and the first terminal are connected to each other, the first antenna connection terminal and the second terminal are connected to each other, the fourth terminal and the sixth terminal are connected to each other, and the fifth terminal and the eighth terminal are connected to each other, and
in a case of simultaneously transferring a signal of the third band and a signal of the fourth band, the first antenna connection terminal and the third terminal are connected to each other.
<4> The radio frequency circuit according to <3>, in which
in a case of simultaneously transferring a transmission signal of the first band and at least one of a signal of the third band and a signal of the fourth band, the first antenna connection terminal and the first terminal are connected to each other, the first antenna connection terminal and the third terminal are connected to each other, and the fourth terminal and the sixth terminal are connected to each other, and
in a case of simultaneously transferring a reception signal of the second band and at least one of a signal of the third band and a signal of the fourth band, the first antenna connection terminal and the second terminal are connected to each other, the first antenna connection terminal and the third terminal are connected to each other, and the fifth terminal and the eighth terminal are connected to each other.
<5> The radio frequency circuit according to <1>, further including:
a second switch including a fourth terminal, a fifth terminal, and a sixth terminal;
a third switch including a seventh terminal, an eighth terminal, and a ninth terminal;
a first power amplifier and a second power amplifier; and
a first low-noise amplifier and a second low-noise amplifier, in which
the fourth terminal is connected to the first filter,
the fifth terminal is connected to the first power amplifier,
the sixth terminal is connected to the first low-noise amplifier,
the seventh terminal is connected to the second filter,
the eighth terminal is connected to the second power amplifier, and
the ninth terminal is connected to the second low-noise amplifier.
<6> The radio frequency circuit according to <5>, in which
the one of a transmission signal and a reception signal of the first band is a transmission signal of the first band,
the other of a transmission signal and a reception signal of the second band is a reception signal of the second band,
in a case of simultaneously transferring a transmission signal of the first band and a reception signal of the second band, the first antenna connection terminal and the first terminal are connected to each other, the first antenna connection terminal and the second terminal are connected to each other, the fourth terminal and the fifth terminal are connected to each other, and the seventh terminal and the ninth terminal are connected to each other, and
in a case of simultaneously transferring a signal of the third band and a signal of the fourth band, the first antenna connection terminal and the third terminal are connected to each other.
<7> The radio frequency circuit according to <6>, in which
in a case of simultaneously transferring a transmission signal of the first band and at least one of a signal of the third band and a signal of the fourth band, the first antenna connection terminal and the first terminal are connected to each other, the first antenna connection terminal and the third terminal are connected to each other, and the fourth terminal and the fifth terminal are connected to each other, and
in a case of simultaneously transferring a reception signal of the second band and at least one of a signal of the third band and a signal of the fourth band, the first antenna connection terminal and the second terminal are connected to each other, the first antenna connection terminal and the third terminal are connected to each other, and the seventh terminal and the ninth terminal are connected to each other.
<8> The radio frequency circuit according to any one of <1> to <7>, further including:
a fifth filter that has a pass band including the first band for time division duplex and that includes an acoustic wave resonator; and
a sixth filter that has a pass band including the second band for time division duplex and that includes an acoustic wave resonator, in which
the first switch further includes a tenth terminal and an eleventh terminal,
the tenth terminal is connected to only the fifth filter among the filters including an acoustic wave resonator, and
the eleventh terminal is connected to only the sixth filter among the filters including an acoustic wave resonator.
<9> The radio frequency circuit according to <8>, in which
in a case of simultaneously transferring one of a transmission signal and a reception signal of the first band and another of a transmission signal and a reception signal of the second band, the first antenna connection terminal and the first terminal are connected to each other, and the first antenna connection terminal and the second terminal are connected to each other,
in a case of simultaneously transferring another of a transmission signal and a reception signal of the first band and one of a transmission signal and a reception signal of the second band, the first antenna connection terminal and the tenth terminal are connected to each other, and the first antenna connection terminal and the eleventh terminal are connected to each other, and
in a case of simultaneously transferring a signal of the third band and a signal of the fourth band, the first antenna connection terminal and the third terminal are connected to each other.
<10> The radio frequency circuit according to <9>, in which
in a case of simultaneously transferring one of a transmission signal and a reception signal of the first band and at least one of a signal of the third band and a signal of the fourth band, the first antenna connection terminal and the first terminal are connected to each other, and the first antenna connection terminal and the third terminal are connected to each other,
in a case of simultaneously transferring another of a transmission signal and a reception signal of the second band and at least one of a signal of the third band and a signal of the fourth band, the first antenna connection terminal and the second terminal are connected to each other, and the first antenna connection terminal and the third terminal are connected to each other,
in a case of simultaneously transferring another of a transmission signal and a reception signal of the first band and at least one of a signal of the third band and a signal of the fourth band, the first antenna connection terminal and the tenth terminal are connected to each other, and the first antenna connection terminal and the third terminal are connected to each other, and
in a case of simultaneously transferring one of a transmission signal and a reception signal of the second band and at least one of a signal of the third band and a signal of the fourth band, the first antenna connection terminal and the eleventh terminal are connected to each other, and the first antenna connection terminal and the third terminal are connected to each other.
<11> The radio frequency circuit according to any one of <1>, <2>, <5>, and <8>, in which
the first switch further includes a second antenna connection terminal,
the first antenna connection terminal is connected to a first antenna,
the second antenna connection terminal is connected to a second antenna, and
in a case of simultaneously transferring one of a transmission signal and a reception signal of the first band and another of a transmission signal and a reception signal of the second band, the first antenna connection terminal and the first terminal are connected to each other, and the second antenna connection terminal and the second terminal are connected to each other.
<12> The radio frequency circuit according to any one of <1> to <11>, further including:
a seventh filter that has a pass band including the first band and that includes an acoustic wave resonator, in which
the seventh filter is connected to the third terminal,
in a case of simultaneously transferring one of a transmission signal and a reception signal of the first band and another of a transmission signal and a reception signal of the second band, the first antenna connection terminal and the first terminal are connected to each other, the first antenna connection terminal and the second terminal are connected to each other, and the first antenna connection terminal and the third terminal are not connected to each other, and
in a case of simultaneously transferring at least one of a signal of the third band and a signal of the fourth band and one of a transmission signal and a reception signal of the first band, the first antenna connection terminal and the first terminal are not connected to each other, the first antenna connection terminal and the second terminal are not connected to each other, and the first antenna connection terminal and the third terminal are connected to each other.
<13> A radio frequency circuit including:
a first filter that has a pass band including a first band for time division duplex and that includes an acoustic wave resonator;
a second filter that has a pass band including a second band for time division duplex and that includes an acoustic wave resonator;
a third filter that has a pass band including a transmission band or a reception band of a third band;
a fourth filter that has a pass band including a transmission band or a reception band of a fourth band; and
a first switch including a first terminal, a second terminal, and a first antenna connection terminal, in which
the first band and the second band constitute a band combination capable of simultaneously transferring one of a transmission signal and a reception signal of the first band and another of a transmission signal and a reception signal of the second band,
the third band and the fourth band constitute a band combination capable of simultaneously transferring a signal of the third band and a signal of the fourth band,
the first band, the second band, the third band, and the fourth band constitute a band combination capable of simultaneously transferring at least one of a signal of the first band and a signal of the second band and at least one of a signal of the third band and a signal of the fourth band,
the first terminal is connected to only the first filter and the second filter among the filters including an acoustic wave resonator, and
the second terminal is connected to the third filter and the fourth filter.
<14> The radio frequency circuit according to any one of <1> to <13>, in which
a combination of the first band and the second band is a combination of Band 40 for Long Term Evolution (LTE) or n40 for 5th Generation New Radio (5G NR) and Band 41 for LTE or n41 for 5G NR, or a combination of Band 39 for LTE or n39 for 5G NR and Band 41 for LTE or n41 for 5G NR.
<15> The radio frequency circuit according to any one of <1> to <14>, in which
a combination of the third band and the fourth band is a combination of two of Band 1, Band 3, Band 25, Band 30, Band 32, and Band 66 for LTE, or a combination of two of n1, n3, n25, n30, n32, and n66 for 5G NR.
<16> A communication device including:
a signal processing circuit configured to process a radio frequency signal; and
the radio frequency circuit according to any one of <1> to <15>, the radio frequency circuit being configured to transfer the radio frequency signal between the signal processing circuit and an antenna.

The present invention can be widely used, as an RF circuit to be disposed in a front end portion, in communication devices such as mobile phones.

What is claimed is:

1. A radio frequency circuit comprising:
a first filter having a pass band including a first band for time division duplex and including an acoustic wave resonator;
a second filter having a pass band including a second band for time division duplex and including an acoustic wave resonator;
a third filter having a pass band including a transmission band or a reception band of a third band;
a fourth filter having a pass band including a transmission band or a reception band of a fourth band; and
a first switch including a first terminal, a second terminal, a third terminal, and a first antenna connection terminal, wherein
the first terminal is connected to only the first filter among the filters including an acoustic wave resonator,
the second terminal is connected to only the second filter among the filters including an acoustic wave resonator, and
the third terminal is connected to the third filter and the fourth filter,
the first band and the second band constitute a band combination configured to simultaneously transfer one of a transmission signal and a reception signal of the first band and another of a transmission signal and a reception signal of the second band,
the third band and the fourth band constitute a band combination configured to simultaneously transfer a signal of the third band and a signal of the fourth band, and
the first band, the second band, the third band, and the fourth band constitute a band combination configured to simultaneously transfer at least one of a signal of the first band and a signal of the second band and at least one of a signal of the third band and a signal of the fourth band.

2. The radio frequency circuit according to claim 1, further comprising:
a second switch including a fourth terminal, a fifth terminal, a sixth terminal, a seventh terminal, and an eighth terminal;
a first power amplifier; and
a first low-noise amplifier and a second low-noise amplifier, wherein
the fourth terminal is connected to the first filter,
the fifth terminal is connected to the second filter,
the sixth terminal is connected to the first power amplifier,
the seventh terminal is connected to the first low-noise amplifier, and
the eighth terminal is connected to the second low-noise amplifier.

3. The radio frequency circuit according to claim 2, wherein
the one of a transmission signal and a reception signal of the first band is a transmission signal of the first band,
the other of a transmission signal and a reception signal of the second band is a reception signal of the second band,
in a case of simultaneously transferring a transmission signal of the first band and a reception signal of the second band, the first antenna connection terminal and the first terminal are connected to each other, the first antenna connection terminal and the second terminal are connected to each other, the fourth terminal and the sixth terminal are connected to each other, and the fifth terminal and the eighth terminal are connected to each other, and
in a case of simultaneously transferring a signal of the third band and a signal of the fourth band, the first antenna connection terminal and the third terminal are connected to each other.

4. The radio frequency circuit according to claim 3, wherein
in a case of simultaneously transferring a transmission signal of the first band and at least one of a signal of the third band and a signal of the fourth band, the first antenna connection terminal and the first terminal are connected to each other, the first antenna connection terminal and the third terminal are connected to each other, and the fourth terminal and the sixth terminal are connected to each other, and
in a case of simultaneously transferring a reception signal of the second band and at least one of a signal of the third band and a signal of the fourth band, the first antenna connection terminal and the second terminal are connected to each other, the first antenna connection terminal and the third terminal are connected to each other, and the fifth terminal and the eighth terminal are connected to each other.

5. The radio frequency circuit according to claim 1, further comprising:
a second switch including a fourth terminal, a fifth terminal, and a sixth terminal;
a third switch including a seventh terminal, an eighth terminal, and a ninth terminal;
a first power amplifier and a second power amplifier; and
a first low-noise amplifier and a second low-noise amplifier, wherein
the fourth terminal is connected to the first filter,
the fifth terminal is connected to the first power amplifier,
the sixth terminal is connected to the first low-noise amplifier,
the seventh terminal is connected to the second filter,
the eighth terminal is connected to the second power amplifier, and
the ninth terminal is connected to the second low-noise amplifier.

6. The radio frequency circuit according to claim 5, wherein
the one of a transmission signal and a reception signal of the first band is a transmission signal of the first band,
the other of a transmission signal and a reception signal of the second band is a reception signal of the second band,
in a case of simultaneously transferring a transmission signal of the first band and a reception signal of the second band, the first antenna connection terminal and the first terminal are connected to each other, the first antenna connection terminal and the second terminal are connected to each other, the fourth terminal and the fifth terminal are connected to each other, and the seventh terminal and the ninth terminal are connected to each other, and
in a case of simultaneously transferring a signal of the third band and a signal of the fourth band, the first antenna connection terminal and the third terminal are connected to each other.

7. The radio frequency circuit according to claim 6, wherein
in a case of simultaneously transferring a transmission signal of the first band and at least one of a signal of the third band and a signal of the fourth band, the first antenna connection terminal and the first terminal are connected to each other, the first antenna connection terminal and the third terminal are connected to each other, and the fourth terminal and the fifth terminal are connected to each other, and
in a case of simultaneously transferring a reception signal of the second band and at least one of a signal of the third band and a signal of the fourth band, the first antenna connection terminal and the second terminal are connected to each other, the first antenna connection terminal and the third terminal are connected to each other, and the seventh terminal and the ninth terminal are connected to each other.

8. The radio frequency circuit according to claim 1, further comprising:
a fifth filter having a pass band including the first band for time division duplex and that includes an acoustic wave resonator; and
a sixth filter having a pass band including the second band for time division duplex and that includes an acoustic wave resonator, wherein
the first switch further includes a tenth terminal and an eleventh terminal,
the tenth terminal is connected to only the fifth filter among the filters including an acoustic wave resonator, and
the eleventh terminal is connected to only the sixth filter among the filters including an acoustic wave resonator.

9. The radio frequency circuit according to claim 8, wherein
in a case of simultaneously transferring one of a transmission signal and a reception signal of the first band and another of a transmission signal and a reception signal of the second band, the first antenna connection terminal and the first terminal are connected to each other, and the first antenna connection terminal and the second terminal are connected to each other,
in a case of simultaneously transferring another of a transmission signal and a reception signal of the first band and one of a transmission signal and a reception signal of the second band, the first antenna connection terminal and the tenth terminal are connected to each other, and the first antenna connection terminal and the eleventh terminal are connected to each other, and
in a case of simultaneously transferring a signal of the third band and a signal of the fourth band, the first antenna connection terminal and the third terminal are connected to each other.

10. The radio frequency circuit according to claim 9, wherein
in a case of simultaneously transferring one of a transmission signal and a reception signal of the first band and at least one of a signal of the third band and a signal of the fourth band, the first antenna connection terminal and the first terminal are connected to each other, and the first antenna connection terminal and the third terminal are connected to each other,
in a case of simultaneously transferring another of a transmission signal and a reception signal of the second band and at least one of a signal of the third band and a signal of the fourth band, the first antenna connection terminal and the second terminal are connected to each other, and the first antenna connection terminal and the third terminal are connected to each other,
in a case of simultaneously transferring another of a transmission signal and a reception signal of the first band and at least one of a signal of the third band and a signal of the fourth band, the first antenna connection terminal and the tenth terminal are connected to each other, and the first antenna connection terminal and the third terminal are connected to each other, and
in a case of simultaneously transferring one of a transmission signal and a reception signal of the second band and at least one of a signal of the third band and a signal of the fourth band, the first antenna connection terminal and the eleventh terminal are connected to each other, and the first antenna connection terminal and the third terminal are connected to each other.

11. The radio frequency circuit according to claim 1, wherein
the first switch further includes a second antenna connection terminal,
the first antenna connection terminal is connected to a first antenna,
the second antenna connection terminal is connected to a second antenna, and
in a case of simultaneously transferring one of a transmission signal and a reception signal of the first band and another of a transmission signal and a reception signal of the second band, the first antenna connection terminal and the first terminal are connected to each other, and the second antenna connection terminal and the second terminal are connected to each other.

12. The radio frequency circuit according to claim 1, further comprising:
a seventh filter having a pass band including the first band and that includes an acoustic wave resonator, wherein
the seventh filter is connected to the third terminal,
in a case of simultaneously transferring one of a transmission signal and a reception signal of the first band and another of a transmission signal and a reception signal of the second band, the first antenna connection terminal and the first terminal are connected to each other, the first antenna connection terminal and the second terminal are connected to each other, and the first antenna connection terminal and the third terminal are not connected to each other, and
in a case of simultaneously transferring at least one of a signal of the third band and a signal of the fourth band and one of a transmission signal and a reception signal of the first band, the first antenna connection terminal and the first terminal are not connected to each other, the first antenna connection terminal and the second terminal are not connected to each other, and the first antenna connection terminal and the third terminal are connected to each other.

13. The radio frequency circuit according to claim 1, wherein
a combination of the first band and the second band is a combination of Band 40 for Long Term Evolution (LTE) or n40 for 5th Generation New Radio (5G NR) and Band 41 for LTE or n41 for 5G NR, or a combination of Band 39 for LTE or n39 for 5G NR and Band 41 for LTE or n41 for 5G NR.

14. The radio frequency circuit according to claim 1, wherein
a combination of the third band and the fourth band is a combination of two of Band 1, Band 3, Band 25, Band 30, Band 32, and Band 66 for LTE, or a combination of two of n1, n3, n25, n30, n32, and n66 for 5G NR.

15. A communication device comprising:
a signal processing circuit configured to process a radio frequency signal; and
the radio frequency circuit according to claim 1, the radio frequency circuit being configured to transfer the radio frequency signal between the signal processing circuit and an antenna.

16. A radio frequency circuit comprising:
a first filter that having a pass band including a first band for time division duplex and including an acoustic wave resonator;
a second filter having a pass band including a second band for time division duplex and including an acoustic wave resonator;
a third filter having a pass band including a transmission band or a reception band of a third band;
a fourth filter having a pass band including a transmission band or a reception band of a fourth band; and
a first switch including a first terminal, a second terminal, and a first antenna connection terminal, wherein
the first terminal is connected to only the first filter and the second filter among the filters including an acoustic wave resonator, and
the second terminal is connected to the third filter and the fourth filter,
the first band and the second band constitute a band combination configured to simultaneously transfer one of a transmission signal and a reception signal of the first band and another of a transmission signal and a reception signal of the second band,
the third band and the fourth band constitute a band combination configured to simultaneously transfer a signal of the third band and a signal of the fourth band,
the first band, the second band, the third band, and the fourth band constitute a band combination configured to simultaneously transfer at least one of a signal of the first band and a signal of the second band and at least one of a signal of the third band and a signal of the fourth band.

17. The radio frequency circuit according to claim 16, wherein
a combination of the first band and the second band is a combination of Band 40 for Long Term Evolution (LTE) or n40 for 5th Generation New Radio (5G NR) and Band 41 for LTE or n41 for 5G NR, or a combination of Band 39 for LTE or n39 for 5G NR and Band 41 for LTE or n41 for 5G NR.

18. The radio frequency circuit according to claim 16, wherein
a combination of the third band and the fourth band is a combination of two of Band 1, Band 3, Band 25, Band 30, Band 32, and Band 66 for LTE, or a combination of two of n1, n3, n25, n30, n32, and n66 for 5G NR.

19. A communication device comprising:
a signal processing circuit configured to process a radio frequency signal; and
the radio frequency circuit according to claim 16, the radio frequency circuit being configured to transfer the radio frequency signal between the signal processing circuit and an antenna.

20. A radio frequency circuit comprising:
a first reception filter having a pass band including a first band for time division duplex (TDD);
a first transmission filter having a pass band including the first band;
a second reception filter having a pass band including a second band for TDD;
a second transmission filter having a pass band including the second band;
a third filter having a pass band including a third band;
a fourth filter having a pass band including a fourth band; and
a switch including a first terminal, a second terminal, a third terminal, a fourth terminal, a fifth terminal, and an antenna connection terminal, wherein
the first terminal is connected to only the first reception filter,
the second terminal is connected to only the first transmission filter,
the third terminal is connected to only the second reception filter,
the fourth terminal is connected to only the second transmission filter, and
the fifth terminal is connected to the third filter and the fourth filter.
